(19) United States
(12) Patent Application Publication
(10) Pub. No.: US 2006/0214204 A1
(43) Pub. Date: Sep. 28, 2006

(54) Ferroelectric structures and devices including upper/lower electrodes of different metals and methods of forming the same

(76) Inventors: Dong-Chul Yoo, Gyeonggi (KR); Byoung Jae Bae, Gyeonggi-do (KR); Ji-Eun Lim, Seoul (KR); Dong-Hyun Im, Seoul (KR); Myung-Gon Kim, Gyeonggi-do (KR)

Correspondence Address: MYERS BIGEL SIBLEY & SAJOVEC, PO BOX 37428, RALEIGH, NC, 27627, US

(21) Appl. No.: 11/270,730

(22) Filed: Nov. 9, 2005

(30) Foreign Application Priority Data
Mar. 23, 2005 (KR) 2005-23904

(51) Int. Cl. H01L 29/94; H01L 29/76

(52) U.S. Cl. 257/295

(57) ABSTRACT

A ferroelectric capacitor structure can include a ferroelectric layer on a lower electrode and an upper electrode on the ferroelectric layer, the upper electrode including a metal oxide and a metal.

### CROSS-REFERENCE TO RELATED APPLICATION

This application claims priority under 35 USC § 119 to Korean Patent Application No. 2005-23904 filed on Mar. 23, 2005, the contents of which are incorporated herein by reference in its entirety.

### FIELD OF THE INVENTION

The present invention relates to integrated circuits in general, and more particularly, to ferroelectric structures in integrated circuits.

### BACKGROUND

A volatile semiconductor memory device, such as a DRAM or an SRAM device, loses data stored therein when power is removed. On the other hand, a nonvolatile semiconductor memory device can maintain data stored therein even though power is removed. However, some conventional nonvolatile memory devices such as a flash memory device, an EPROM device or an EEPROM device may also have some disadvantages such as relatively low integration, relatively slow speed, high power consumption, etc.

FRAM (ferroelectric random access memory) devices have been considered as alternatives to the flash memories discussed above. In general, a ferroelectric material operates according to a hysteresis loop of a polarization when a voltage is applied to the ferroelectric material. The FRAM device including the ferroelectric material has a stable polarization state by applying an electric field thereto so that the FRAM device can store data therein when power is removed. The FRAM device has been widely employed in various electronic apparatuses because FRAM has some advantages such as fast response speed, lower power consumption, high reliability, etc. At present, a ferroelectric materials such as PZT [Pb(Zr, Ti)O₃1, SBT (SrBi₂Ta₂O₉) or BLT [(Bi, La)TiO₃] have been used in ferroelectric capacitors in FRAMs.

Ferroelectric capacitors are discussed in U.S. Pat. No. 6,351,006 issued to Yamakawa et. al, U.S. Pat. No. 6,194,228 issued to Fujiki et. al, and U.S. Patent Application Publication No. 2003/0102500. FIG. 1 is a cross-sectional view illustrating the conventional ferroelectric capacitor discussed in the above U.S. Pat. No. 6,351,006.

Referring to FIG. 1, the conventional ferroelectric capacitor includes a lower electrode 25, a PZT layer 28 and an upper electrode 37. The lower electrode 25 has a first platinum layer 19 and a first strontium ruthenium oxide (SrRuO₃; SRO) 22. The upper electrode 37 has a second SRO layer 31 and a second platinum layer 34.

The lower electrode 25 is positioned on a first insulating interlayer 13 formed on a semiconductor substrate 10. An adhesion layer 16 is interposed between the insulation layer 13 and the lower electrode 25.

The PZT layer 28 and the upper electrode 37 are sequentially formed on the lower electrode 25. A second insulating interlayer 40 is formed on the lower electrode 25 and the first insulating interlayer 13 to cover the PZT layer 28 and the upper electrode 37.

A hole (not shown) is formed through the second insulating interlayer 40 to expose the second platinum layer 34 of the upper electrode 37. A barrier layer 43 of titanium nitride is formed on the exposed second platinum layer 34 and a sidewall of the hole. An aluminum wiring is formed on the barrier layer 43. The wiring is electrically connected to the upper electrode 37.

### SUMMARY

Embodiments according to the invention can provide ferroelectric structures and devices including upper/lower electrodes of different metals and methods of forming the same. Pursuant to these embodiments a ferroelectric capacitor structure can include a ferroelectric layer on a lower electrode and an upper electrode on the ferroelectric layer, the upper electrode including a metal oxide and a metal. In some embodiments according to the invention, the metal is different than a metal constituent in the metal oxide.

In some embodiments according to the invention, the metal is about 2 percent to about 5 percent of a total atomic weight of the metal oxide. In some embodiments according to the invention, the metal oxide is strontium ruthenium oxide (SRO), strontium titanium oxide (STO), lanthanum nickel oxide (LNO) and/or calcium ruthenium oxide (CRO) and the metal is copper, lead and/or bismuth. In some embodiments according to the invention, the metal is a first metal and the upper electrode is a second metal that is different than the first metal.

In some embodiments according to the invention, the second metal is iridium (Ir), platinum (Pt), ruthenium (Ru), palladium (Pd) and/or gold (Au). In some embodiments according to the invention, the metal oxide and the first metal comprise a first upper electrode layer and the upper electrode further includes a second upper electrode on the first upper electrode comprising the second metal.

In some embodiments according to the invention, the lower electrode is a third metal that is different than or same as the second metal. In some embodiments according to the invention, the third metal is iridium (Ir), platinum (Pt), ruthenium (Ru), palladium (Pd) and/or gold (Au). In some embodiments according to the invention, the third metal is a first lower electrode layer in the lower electrode and the metal oxide is a first metal oxide. The capacitor further includes a second lower electrode layer on the first lower electrode layer, the second lower electrode layer comprising a second metal oxide and a fourth metal.

In some embodiments according to the invention, the second metal oxide is a different metal oxide or same metal oxide as the first metal oxide. In some embodiments according to the invention, the fourth metal is a different metal or same metal as the first metal. In some embodiments according to the invention, the fourth metal is about 2 percent to about 5 percent of a total atomic weight of the second metal oxide.

In some embodiments according to the invention, the second metal oxide is strontium ruthenium oxide (SRO), strontium titanium oxide (STO), lanthanum nickel oxide (LNO) and/or calcium ruthenium oxide (CRO) and the fourth metal is copper, lead and/or bismuth. In some embodiments according to the invention, the capacitor further includes a third lower electrode layer comprising a metal nitride beneath the first lower electrode layer.

In some embodiments according to the invention, the third lower electrode is titanium aluminum nitride (TiAlN), aluminum nitride (AlN), titanium nitride (TiN), titanium silicon nitride (TiSiN), tantalum nitride (TaN), tantalum silicon nitride (TaSiN) and/or tungsten nitride (WN). In some embodiments according to the invention, the first upper electrode layer is a thickness of about 10 to about 300 Å, and the second upper electrode layer is a thickness of about 300 to about 1,000 Å.

In some embodiments according to the invention, the capacitor further includes an insulation layer between the lower electrode and a substrate thereunder and an adhesion layer beneath on the insulation layer beneath the lower electrode.

In some embodiments according to the invention, the adhesion layer is a metal or a metal nitride.

In some embodiments according to the invention, the adhesion layer is titanium (Ti), tantalum (Ta), aluminum (Al), tungsten (W), titanium nitride (TiN), tantalum nitride (TaN), aluminum nitride (AlN) and/or tungsten nitride (WN).

In some embodiments according to the invention, a ferroelectric capacitor structure includes a ferroelectric layer on a lower electrode and an upper electrode on the ferroelectric layer, the upper electrode including a metal oxide, a first metal, and a second metal that is different than the first metal. In some embodiments according to the invention, the first metal and the metal oxide are included in a first upper electrode layer and the second metal is included in a second upper electrode layer on the first upper electrode layer.

In some embodiments according to the invention, the first metal is about 2 percent to about 5 percent of a total atomic weight of the metal oxide. In some embodiments according to the invention, the metal oxide is strontium ruthenium oxide (SRO), strontium titanium oxide (STO), lanthanum nickel oxide (LNO) and/or calcium ruthenium oxide (CRO) and the first metal is copper, lead and/or bismuth. In some embodiments according to the invention, the second metal is iridium (Ir), platinum (Pt), ruthenium (Ru), palladium (Pd) and/or gold (Au).

In some embodiments according to the invention, a ferroelectric capacitor includes a first lower electrode layer comprising a metal nitride. A second lower electrode layer is on the first lower electrode layer and is a first metal. A third lower electrode layer is on second lower electrode layer, and is a first metal oxide and a second metal that is different than the first metal. A PZT ferroelectric layer is directly on the third lower electrode layer. A first upper electrode layer is on the PZT ferroelectric layer, and is a second metal oxide and a third metal. A second upper electrode layer is on the first upper electrode layer, and includes a fourth metal that is different than the third metal.

In some embodiments according to the invention, a ferroelectric capacitor structure includes a first lower electrode layer of a metal nitride. A second lower electrode layer, is on the first lower electrode layer, and is a first metal. A PZT ferroelectric layer is directly on the second lower electrode layer. A first upper electrode layer is on the PZT ferroelectric layer, and includes a metal oxide and a second metal. A second upper electrode layer, is on the first upper electrode layer, and includes a third metal that is different than the second metal.

In some embodiments according to the invention, a method of forming a ferroelectric capacitor structure includes forming a ferroelectric layer on a lower electrode and forming an upper electrode on the ferroelectric layer, the upper electrode including a metal oxide and a metal.

In some embodiments according to the invention, a method of forming a ferroelectric capacitor structure includes forming a first lower electrode layer of a metal nitride using CVD, sputtering, or ALD. A second lower electrode layer is formed on the first lower electrode layer, including a first metal using ALD, PLD, or sputtering, wherein the first metal is iridium (Ir), platinum (Pt), ruthenium (Ru), palladium (Pd) and/or gold (Au). A third lower electrode layer is formed on second lower electrode layer, including a first metal oxide and a second metal that is different than the first metal using ALD, PLD, or sputtering, wherein the second metal is about 2 percent to about 5 percent of a total atomic weight of the first metal oxide. A PZT ferroelectric layer is formed directly on the third lower electrode layer. A first upper electrode layer is formed on the PZT ferroelectric layer, using ALD, PLD, or sputtering to provide a second metal oxide and a third metal, wherein the third metal is about 2 percent to about 5 percent of a total atomic weight of the second metal oxide. A second upper electrode layer is formed on the first upper electrode layer, including a fourth metal that is different than the third metal using ALD, PLD, or sputtering, wherein the fourth metal is iridium (Ir), platinum (Pt), ruthenium (Ru), palladium (Pd) and/or gold (Au).

### BRIEF DESCRIPTION OF THE DRAWINGS

FIG. 1 is cross-sectional view illustrating a conventional ferroelectric capacitor;

FIG. 2 is a cross-sectional view illustrating a ferroelectric structure in accordance some exemplary embodiments of the present invention;

FIG. 3 is a cross-sectional view illustrating a ferroelectric structure in accordance some exemplary embodiments of the present invention;

FIG. 4 is a cross-sectional view illustrating a ferroelectric capacitor in accordance some exemplary embodiments of the present invention;

FIGS. 5 to 8 are cross-sectional views illustrating methods of manufacturing the ferroelectric capacitor in FIG. 4;

FIG. 9 is a schematic cross-sectional view illustrating an apparatus for a metal organic chemical vapor deposition process in accordance with some exemplary embodiments of the present invention;

FIG. 10 is a cross-sectional view illustrating a ferroelectric capacitor in accordance some exemplary embodiments of the present invention;

FIGS. 11 to 13 are cross-sectional views illustrating methods of manufacturing the ferroelectric capacitor in FIG. 10;

FIG. 14 is a graph showing a P-V hysteresis loop of a ferroelectric capacitor in accordance with Example 1;

FIG. 15 is a graph showing a P-V hysteresis loop of a ferroelectric capacitor in accordance with Example 2;

FIG. 16 is a graph showing a P-V hysteresis loop of a ferroelectric capacitor in accordance with Example 3;

FIG. 17 is a graph showing a P-V hysteresis loop of a ferroelectric capacitor in accordance with Example 4;

FIG. 18 is a graph showing a P-V hysteresis loop of a ferroelectric capacitor in accordance with Example 5;

FIG. 19 is a graph showing a P-V hysteresis loop of a ferroelectric capacitor in accordance with Example 6;

FIG. 20 is a graph showing a P-V hysteresis loop of a ferroelectric capacitor in accordance with Example 7;

FIG. 21 is a graph showing a P-V hysteresis loop of a ferroelectric capacitor in accordance with Example 8;

FIG. 22 is a graph showing a P-V hysteresis loop of a ferroelectric capacitor in accordance with Example 9;

FIG. 23 is a graph showing a P-V hysteresis loop of a ferroelectric capacitor in accordance with Example 10;

FIG. 24 is a graph showing a P-V hysteresis loop of a ferroelectric capacitor in accordance with Example 11;

FIG. 25 is a graph showing a P-V hysteresis loop of a ferroelectric capacitor in accordance with Example 12;

FIG. 26 is a graph showing a P-V hysteresis loop of a ferroelectric capacitor in accordance with Comparative Example 1;

FIG. 27 is a graph showing Q-V characteristics of the ferroelectric capacitors of Comparative Example 1 and Examples 1, 2, 4 to 9 and 11;

FIGS. 28 and 29 are graphs showing retention characteristics of the ferroelectric capacitors of Comparative Example 1 and Examples 1 and 7;

FIG. 30 is a graph showing a P-V hysteresis loop of a ferroelectric capacitor in accordance with Example 13;

FIG. 31 is a graph showing a P-V hysteresis loop of a ferroelectric capacitor in accordance with Example 14;

FIG. 32 is a graph showing a P-V hysteresis loop of a ferroelectric capacitor in accordance with Example 15;

FIG. 33 is a graph showing a P-V hysteresis loop of a ferroelectric capacitor in accordance with Example 16;

FIG. 34 is a graph showing a P-V hysteresis loop of a ferroelectric capacitor in accordance with Example 17;

FIG. 35 is a graph showing a P-V hysteresis loop of a ferroelectric capacitor in accordance with Comparative Example 2;

FIG. 36 is a graph showing retention characteristics of the ferroelectric capacitors of Comparative Example 2 and Examples 13 and 17;

FIG. 37 is a graph showing Q-V characteristics of the ferroelectric capacitors of Comparative Example 2 and Examples 13 and 17;

FIG. 38 is a graph showing retention characteristics of the ferroelectric capacitors of Comparative Example 2 and Examples 13 and 17; and

FIGS. 39 to 45 are cross-sectional views illustrating a semiconductor device including a ferroelectric structure in accordance with some exemplary embodiments of the present invention.

FIG. 46 is a schematic illustration of a conventional sputtering apparatus that may be used to form ferroelectric capacitors and structures in some embodiments according to the present invention.

### DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

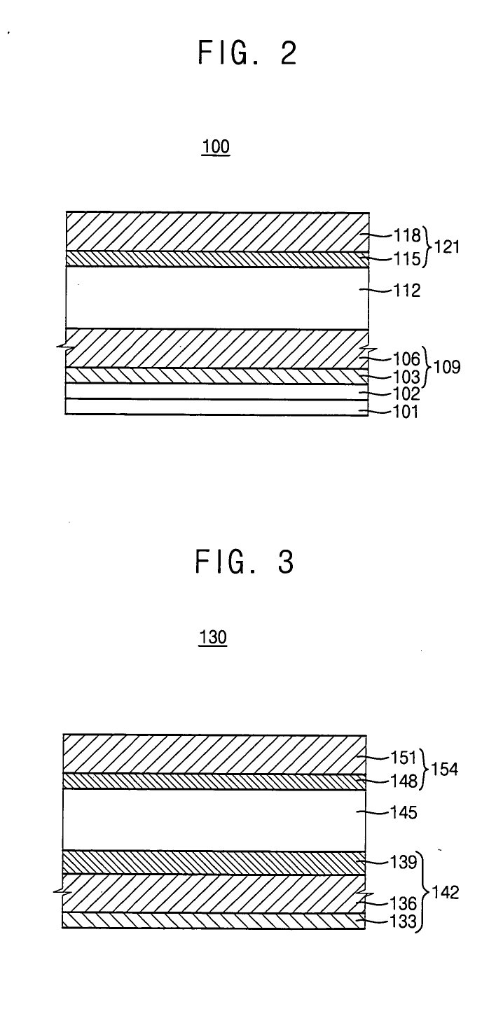

FIG. 2 is a cross-sectional view illustrating a ferroelectric structure in accordance some exemplary embodiments of the present invention. Referring to FIG. 2, a ferroelectric structure 100 includes a lower electrode 109, a ferroelectric layer 112 formed on the lower electrode 109, and an upper electrode 121 formed on the ferroelectric layer 112.

The lower electrode 109 may be formed on a substrate such as a silicon wafer or a silicon-on-insulator (SOI) substrate. The substrate may include a conductive structure formed thereon. The conductive structure may include a contact region, a pad, a plug, a conductive wiring, a conductive pattern, a transistor, etc.

The lower electrode 109 includes a first lower electrode layer 103 and a second lower electrode layer 106. The first lower electrode layer 103 may be formed on the substrate, and the second lower electrode layer 106 is formed on the first lower electrode layer 103.

In some embodiments of the present invention, an insulation layer 101 may be formed between the lower electrode 109 and the substrate to cover the conductive structure. In some embodiments according to the present invention, an adhesion layer 102 may be formed between the lower electrode 109 and the substrate or between the lower electrode 109 and the insulation layer. The adhesion layer may increase an adhesive strength between the lower electrode 109 and the substrate or between the lower electrode 109 and the insulation layer. The adhesion layer may include a metal or a conductive metal nitride. For example, the adhesion layer may include titanium (Ti), titanium nitride (TiN), tantalum (Ta), tantalum nitride (TaN), aluminum (Al), aluminum nitride (AIN), tungsten (W), and/or tungsten nitride (WN), etc.

The first lower electrode layer 103 may reduce diffusion of oxygen atoms from the ferroelectric layer 112. That is, the first lower electrode layer 103 may serve as a diffusion barrier layer to reduce the diffusion of the oxygen atoms contained in the ferroelectric layer 112. The second lower electrode layer 106 improves a crystallization of ingredients included in the ferroelectric layer 112. Additionally, the first lower electrode layer 103 improves the adhesive strength between the second lower electrode layer 106 and the substrate or the insulation layer when the adhesion layer may not be formed beneath the lower electrode 109. The first lower electrode layer 103 simultaneously serves as a diffusion barrier layer and an adhesion layer.

The first lower electrode layer 103 may include a metal nitride. For example, the first lower electrode layer 103 includes titanium aluminum nitride (TiAlN), aluminum nitride (AlN), titanium nitride (TiN), titanium silicon nitride (TiSiN), tantalum nitride (TaN), tantalum silicon nitride (TaSiN), and/or tungsten nitride (WN), etc. The first lower electrode layer 103 may be formed by a chemical vapor deposition (CVD) process, an atomic layer deposition (ALD) process or a sputtering process. For example, the first lower electrode layer 103 is formed by the ALD process using titanium aluminum nitride. The first lower electrode layer 103 may have a thickness of about 50 to about 300 Å.

The second lower electrode layer 106 may include a first metal such as iridium (Ir), platinum (Pt), ruthenium (Ru), palladium (Pa) or gold (Au). The second lower electrode layer 106 may be formed by a sputtering process, a pulse laser deposition (PLD) process or an ALD process. For example, the second lower electrode layer 106 is formed by the sputtering process using iridium. The second lower electrode layer 106 may have a thickness of about 300 to about 1,000 Å.

The ferroelectric layer 112 is formed on the second lower electrode layer 106. The ferroelectric layer 112 may include a ferroelectric material such as PZT [Pb(Zr, Ti)O₃], SBT (SrBi₂Ta₂O₉), BLT [(Bi. La)TiO₃], PLZT [Pb(La, Zr)TiO₃], BST [(Bi, Sr)TiO₃], etc. When the ferroelectric layer 112 includes PZT, PZT may include zirconium (Zr) and titanium (Ti) by a weight ratio of about 25:75 to about 40:60.

In some embodiments of the present invention, the ferroelectric layer 112 may include a ferroelectric material doped with a metal such as calcium (Ca), lanthanum (La), manganese (Mn) or bismuth (Bi). For example, the ferroelectric layer 112 includes PZT, SBT, BLT, PLZT or BST doped with Ca, La, Mn or Bi.

In another embodiment of the present invention, the ferroelectric layer 112 may include a metal oxide such as titanium oxide (TiO_{X}), tantalum oxide (TaO_{X}), aluminum oxide (AlO_{X}), zinc oxide (ZnO_{X}), hafnium oxide (HfO_{X}), etc.

The ferroelectric layer 112 may be formed on the second lower electrode layer 106 by a metal organic chemical vapor deposition process, a sol-gel process or an ALD process. For example, the ferroelectric layer 112 is formed using PZT by the metal organic chemical vapor deposition process. Here, the ferroelectric layer 112 may include PZT that contains zirconium and titanium by a weight ratio of about 35:65. The ferroelectric layer 112 may have a thickness of about 200 to about 1,000 Å.

The upper electrode 121 includes a first upper electrode layer 115 and a second upper electrode layer 118 sequentially formed on the ferroelectric layer 112. The first upper electrode layer 115 may include a first metal oxide doped with a second metal by a concentration of about 2 to about 5 atomic weight percent based on an entire atomic weight of the first metal oxide.

In some embodiments according to the invention, the upper electrode 115 is formed by sputtering a target of metal oxide that is doped with the second metal at the concentrations described above. Accordingly, the sputtering will lead to the formation of the upper electrode 115 that includes the metal oxide as well as the doped second metal at the concentration found in the target. For example, if the target is SRO doped with copper as described above (i.e., about 2% to about 5%), it will be understood that the copper accounts for about 2% to about 5% of the total atomic weight of the SRO and the copper dopant. Moreover, the amount of doping provided in the metal oxide may vary among the different dopants used. For example, if Bi or Pb are used as the dopant (rather than Cu), the amount of Bi or Pb in the SRO will be different due to the different atmic weights of Bi, Pb, and Cu. Accordingly, the amount of Cu in the SRO, the amount of Bi in the SRO, and the amount of Pb in the SRO may all be different due to the corresponding different atomic weights.

The first metal oxide may include strontium ruthenium oxide (SrRuO₃; SRO), strontium titanium oxide (SrTiO₃; STO), lanthanum nickel oxide (LaNiO₃; LNO) or calcium ruthenium oxide (CaRuO₃; CRO). The second metal may include copper (Cu), lead (Pb) or bismuth (Bi). The first upper electrode layer 115 may be formed on the ferroelectric layer 112 by a sputtering process, a PLD process or an ALD process. For example, the first upper electrode layer 115 is formed by the sputtering process using SRO doped with the second metal by a concentration of about 2 to about 5 atomic weight percent based on an entire atomic weight of SRO. The first upper electrode layer 115 may have a thickness of about 10 to about 300 Å.

The second upper electrode layer 118 may include a third metal such as iridium, ruthenium, platinum, palladium or gold. The second upper electrode layer 118 may be formed on the first upper electrode layer 115 by a sputtering process, a PLD process or an ALD process. For example, the second upper electrode layer 118 is formed on the first upper electrode layer 115 by the sputtering process using iridium. The second upper electrode layer 118 may have a thickness of about 300 to about 1,000 Å.

In some embodiments of the present invention, the first metal included in the second lower electrode layer 106 may be substantially identical to the third metal contained in the second upper electrode layer 118. For example, each of the first metal and the third metal may correspond to iridium, ruthenium, platinum, palladium or gold.

In another embodiment of the present invention, the first metal in the second lower electrode layer 106 may be different from the third metal in the second upper electrode layer 118. For example, each of the first metal and the third metal may correspond to different one among iridium, ruthenium, platinum, palladium and gold.

After forming the second upper electrode layer 118, the ferroelectric structure 100 having the ferroelectric layer 112 and the upper electrode 121 is thermally treated. Thus, ingredients in the ferroelectric layer 112 and the first upper electrode layer 115 can be crystallized. The ferroelectric layer 112 and the upper electrode 121 may be thermally treated using a rapid thermal process (RTP) under an oxygen atmosphere, a nitrogen atmosphere or a mixture atmosphere including oxygen and nitrogen. The ferroelectric layer 112 and the upper electrode 121 may be treated at a temperature of about 500 to about 650° C. for about 30 seconds to about 3 minutes.

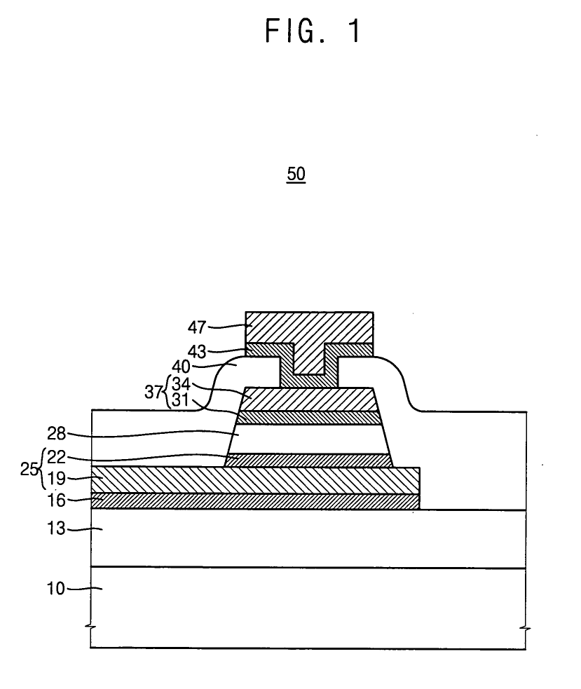

As appreciated by the present inventors, in some conventional ferroelectric capacitors (such as that shown in FIG. 1), the upper and the lower electrodes 37 and 25 include SRO so that the conventional ferroelectric capacitor may have improved retention and fatigue characteristics. However, some SRO particles may remain after an etching process to form the upper and the lower electrodes when the upper and the lower electrodes include SRO only. Additionally, when the upper and the lower electrodes include SRO only the upper and the lower electrodes may have relatively low density.

As further appreciated by the present inventors, platinum in the upper and the lower electrodes may act as a catalyst relative to hydrogen, so that the retention of the PZT layer may be accelerated and also the upper and the lower electrodes may be more readily oxidized. As a result, such as ferroelectric capacitor may have poor ferroelectric and electrical characteristics.

As further appreciated by the present inventors, if the conventional lower electrode and/or the upper electrode were to include iridium oxide (IrO₂) instead of platinum, processing conditions, such as temperature, gas atmosphere and pressure a heat treatment process for the upper electrode and the PZT layer may need to be precisely controlled. In addition, increased leakage currents may be generated by the conventional upper electrode or the lower electrode so that the electrical characteristics of a conventional ferroelectric capacitor may be adversely affected.

FIG. 3 is a cross-sectional view illustrating a ferroelectric structure in accordance with some exemplary embodiments of the present invention. Referring to FIG. 3, a ferroelectric structure 130 includes a lower electrode 142 including a first lower electrode layer 133, a second lower electrode layer 136 and a third lower electrode layer 139, a ferroelectric layer 145 formed on the lower electrode 142, and an upper electrode 154 including a first upper electrode layer 148 and a second upper electrode layer 151 sequentially formed on the ferroelectric layer 154. In the some embodiments, the second lower electrode layer 136 may include a first metal, and the first upper electrode layer 148 may include a first metal oxide doped with a second metal. Additionally, the second upper electrode layer 151 may include a third metal, and the third lower electrode layer 139 may include a second metal oxide doped with a fourth metal.

As described above, the lower electrode 142 may be formed on a substrate such as a silicon wafer or an SOI substrate. The substrate may further include a conductive structure such as a contact region, a pad, a plug, a conductive wiring, a conductive pattern, a transistor, etc.

The first lower electrode layer 133, the second lower electrode layer 136, and the third lower electrode layer 139 may be sequentially formed on the substrate. An insulation layer may be formed between the first lower electrode layer 133 and the substrate to cover the conductive structure. An adhesion layer may be formed between the first lower electrode layer 133 and the substrate or between the first lower electrode layer 133 and the insulation layer. The adhesion layer may increase an adhesive strength between the first lower electrode layer 133 and the substrate or between the first lower electrode layer 133 and the insulation layer. The adhesion layer may include a metal or a conductive metal nitride such as titanium, titanium nitride, tantalum, tantalum nitride, aluminum, aluminum nitride, tungsten, tungsten nitride, etc.

The first lower electrode layer 133 reduces diffusion of oxygen atoms from the ferroelectric layer 145, and the second lower electrode layer 136 improves a crystallization of ingredients included in the ferroelectric layer 145. In addition, the first lower electrode layer 133 improves the adhesive strength between the second lower electrode layer 136 and the substrate or the insulation layer when the adhesion layer may not be formed beneath the first lower electrode layer 133.

The first lower electrode layer 133 may include a metal nitride such as titanium aluminum nitride, aluminum nitride, titanium nitride, titanium silicon nitride, tantalum nitride, tantalum silicon nitride, tungsten nitride, etc. The first lower electrode layer 133 may be formed on the substrate or the insulation layer by a CVD process, an ALD process or a sputtering process. For example, the first lower electrode layer 133 is formed on the substrate or the insulation layer by the ALD process using titanium aluminum nitride. The first lower electrode layer 133 may have a thickness of about 50 to about 300 Å.

The second lower electrode layer 136 may include the first metal such as iridium, platinum, ruthenium, palladium or gold. The second lower electrode layer 136 may be formed on the first lower electrode layer 133 by a sputtering process, a PLD process or an ALD process. For example, the second lower electrode layer 136 is formed on the first lower electrode layer 133 by the sputtering process using iridium. The second lower electrode layer 136 may have a thickness of about 300 to about 1,000 Å.

The third lower electrode layer 139 may include the second metal oxide doped with the fourth metal by a concentration of about 2 to about 5 atomic weight percent based on an entire atomic weight of the second metal oxide. The second metal oxide may include strontium ruthenium oxide (SRO), strontium titanium oxide (STO), lanthanum nickel oxide (LNO) or calcium ruthenium oxide (CRO). The fourth metal may include copper, lead or bismuth. The third lower electrode layer 139 may be formed on the second lower electrode layer 136 by a sputtering process, a PLD process or an ALD process. For example, the third lower electrode layer 139 is formed by the sputtering process using SRO doped with the fourth metal by a concentration of about 2 to about 5 atomic weight percent based on SRO. The third lower electrode layer 139 may have a thickness of about 10 to about 500 Å.

The ferroelectric layer 145 is formed on the third lower electrode layer 139. The ferroelectric layer 145 may include a ferroelectric material such as PZT, SBT, BLT, PLZT, BST, etc. When the ferroelectric layer 145 includes PZT, PZT may include zirconium and titanium by a weight ratio of about 25:75 to about 40:60. The ferroelectric layer 145 may include the ferroelectric material doped with a metal such as calcium, lanthanum, manganese or bismuth. For example, the ferroelectric layer 145 includes PZT, SBT, BLT, PLZT or BST doped with calcium, lanthanum, manganese or bismuth. The ferroelectric layer 145 may include a metal oxide such as titanium oxide, tantalum oxide, aluminum oxide, zinc oxide, hafnium oxide, etc.

The ferroelectric layer 145 may be formed on the third lower electrode layer 139 by a metal organic chemical vapor deposition process, a sol-gel process or an ALD process. For example, the ferroelectric layer 145 is formed by the metal organic chemical vapor deposition process using PZT that contains zirconium and titanium by a weight ratio of about 35:65. The ferroelectric layer 145 may have a thickness of about 200 to about 1,000 Å.

The first upper electrode layer 148 is formed on the ferroelectric layer 145. The first upper electrode layer 148 may include the first metal oxide doped with the second metal by a concentration of about 2 to about 5 atomic weight percent based on an entire atomic weight of the first metal oxide. The first metal oxide may include SRO, STO, LNO or CRO. The second metal may include copper, lead or bismuth. The first upper electrode layer 148 may be formed on the ferroelectric layer 145 by a sputtering process, a PLD process or an ALD process. For example, the first upper electrode layer 148 is formed by the sputtering process using SRO doped with the second metal by a concentration of about 2 to about 5 atomic weight percent based on an entire atomic weight of SRO. The first upper electrode layer 148 may have a thickness of about 10 to about 300 Å.

In some embodiments of the present invention, the first metal oxide in the first upper electrode layer 148 may be substantially identical to the second metal oxide in the third lower electrode layer 139. Additionally, the second metal in the first upper electrode layer 148 may be substantially identical to the fourth metal in the third lower electrode layer 139. For example, each of the first metal oxide and the second metal oxide may correspond to SRO, STO, LNO or CRO, and each of the second metal and the fourth metal may correspond to copper, lead or bismuth.

In another embodiment of the present invention, the first metal oxide in the first upper electrode layer 148 may be different from the second metal oxide in the third lower electrode layer 139. In addition, the second metal in the first upper electrode layer 148 may be also different from the fourth metal in the third lower electrode layer 139. For example, each of the first metal oxide and the second metal oxide may correspond to different one among SRO, STO, LNO and CRO, and also each of the second metal and the fourth metal may correspond to different one among copper, lead and bismuth.

The second upper electrode layer 151 is formed on the first upper electrode layer 148. The second upper electrode layer 151 may include the third metal such as iridium, ruthenium, platinum, palladium or gold. The second upper electrode layer 151 may be formed on the first upper electrode layer 148 by a sputtering process, a PLD process or an ALD process. For example, the second upper electrode layer 151 is formed on the first upper electrode layer 148 by the sputtering process using iridium. The second upper electrode layer 151 may have a thickness of about 300 to about 1,000 Å.

As described above, the first metal included in the second lower electrode layer 136 may be substantially identical to the third metal contained in the second upper electrode layer 151. For example, each of the first metal and the third metal may correspond to iridium, ruthenium, platinum, palladium or gold. On the other hands, the first metal in the second lower electrode layer 136 may be different from the third metal in the second upper electrode layer 151. For example, each of the first metal and the third metal may correspond to different one among iridium, ruthenium, platinum, palladium and gold.

After forming the second upper electrode layer 151 on the first upper electrode layer 148, the ferroelectric structure 130 having the ferroelectric layer 145 and the upper electrode 154 is thermally treated so that ingredients in the ferroelectric layer 145 and the first upper electrode layer 151 are crystallized. The ferroelectric layer 145 and the upper electrode 154 may be thermally treated using a RTP under an oxygen atmosphere, a nitrogen atmosphere or a mixture atmosphere including oxygen and nitrogen. The ferroelectric layer 145 and the upper electrode 154 may be treated at a temperature of about 500 to about 650° C. for about 30 seconds to about 3 minutes.

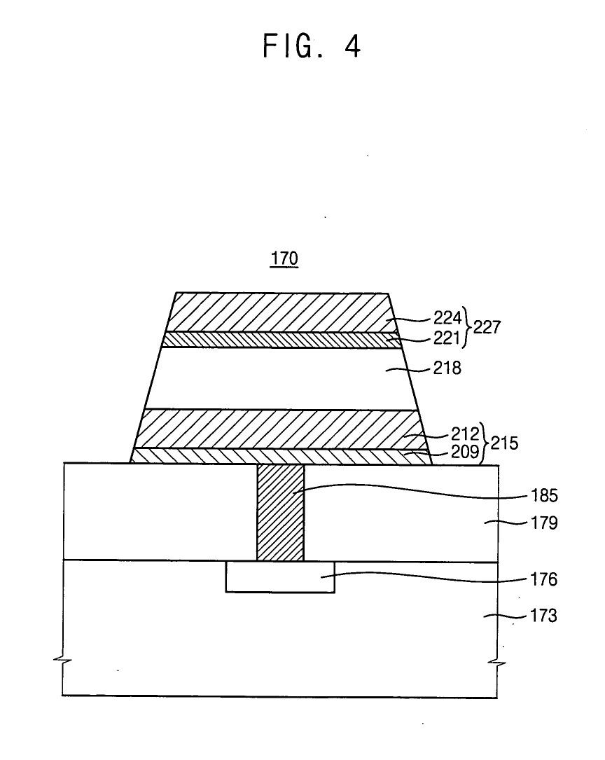

FIG. 4 is a cross-sectional view illustrating a ferroelectric capacitor in accordance with some exemplary embodiments of the present invention.

Referring to FIG. 4, a ferroelectric capacitor 170 includes a lower electrode 215 formed over a semiconductor substrate 173, a ferroelectric layer pattern 218 formed on the lower electrode 215, and an upper electrode 227 formed on the ferroelectric layer pattern 218.

An insulation layer 179 is formed between the lower electrode 215 and the substrate 173. The insulation layer 179 is formed on the substrate 173 to cover a conductive structure 176 formed on the substrate 173. The conductive structure 176 may include a contact region, a pad, a plug, a transistor, a conductive wiring, a conductive pattern, etc.

The insulation layer 179 may include an oxide. For example, the insulation layer 179 includes boro-phosphor silicate glass (BPSG), phosphor silicate glass (PSG), undoped silicate glass (USG), spin on glass (SOG), flowable oxide (FOX), plasma enhanced tetra ethyl ortho silicate (PE-TEOS), high density plasma chemical vapor deposition (HDP-CVD) oxide, etc.

A pad 185 or a contact is formed through the insulation layer 179. The pad 185 makes contact with the conductive structure 176 to thereby electrically connect the lower electrode 215 to the conductive structure 176. The pad 185 may include a metal or a conductive metal nitride. For example, the pad 185 includes tungsten (W), aluminum (Al), copper (Cu), titanium (Ti), tungsten nitride (WN), aluminum nitride (AIN), titanium nitride (TiN), etc.

The lower electrode 215 includes a first lower electrode layer pattern 209 and a second lower electrode layer pattern 212 sequentially formed on the pad 185 and the insulation layer 179.

An adhesion layer (not shown) may be formed beneath the first lower electrode layer pattern 209 to improve an adhesive strength between the insulation layer 179 and the first lower electrode layer pattern 209. The adhesion layer may include a metal or a conductive metal nitride such as titanium, tantalum, aluminum, tungsten, titanium nitride, aluminum nitride, tantalum nitride, tungsten nitride, etc.

In some embodiments on the present invention, the adhesion layer may include the metal or the conductive metal nitride substantially identical to that of the pad 185. In another embodiment of the present invention, the adhesion layer may include the metal or the conductive metal nitride different from that of the pad 185.

The lower electrode 215 has a sidewall inclined by a predetermined angle relative to a horizontal direction parallel to the substrate 173. For example, the sidewall of the lower electrode 215 is inclined by an angle of about 50 to about 80° with respect to the horizontal direction. In other words, the lower electrode 215 may have a general pyramid or mesa structure. As a result, the first lower electrode layer pattern 209 has a size substantially larger than that of the second lower electrode layer pattern 212.

The first lower electrode layer pattern 209 can reduce diffusion of oxygen atoms from the ferroelectric layer pattern 218, and the second lower electrode layer pattern 212 improves a crystallization of ingredients included in the ferroelectric layer pattern 218. Further, the first lower electrode layer pattern 209 enhances an adhesive strength between the insulation layer 179 and the second lower electrode layer pattern 212 when the adhesion layer is not formed.

The first lower electrode layer pattern 209 may include a metal nitride such as titanium aluminum nitride, aluminum nitride, titanium nitride, titanium silicon nitride, tantalum nitride, tungsten nitride, tantalum silicon nitride, etc. The first lower electrode layer pattern 209 may have a thickness of about 50 to about 300 Å. The second lower electrode layer pattern 212 may include a first metal such as iridium, ruthenium, platinum, palladium or gold. The second lower electrode layer pattern 212 may have a thickness of about 300 to about 1,000 Å. For example, the first and the second lower electrode layer patterns 209 and 212 include titanium aluminum nitride and iridium, respectively.

The ferroelectric layer pattern 218 is formed on the second lower electrode layer pattern 212. The ferroelectric layer pattern 218 may be smaller than the second lower electrode layer pattern 212. As the sidewall of the lower electrode 215, the ferroelectric layer pattern 218 has a sidewall inclined by a predetermined angle with respect to the horizontal direction parallel to the substrate 173. For example, the sidewall of the ferroelectric layer pattern 218 is inclined by an angle of about 50 to about 80° relative to the horizontal direction. The ferroelectric layer pattern 218 may include a ferroelectric material such as PZT, SBT, BLT, PLZT, BST, etc. Alternatively, the ferroelectric layer pattern 218 may include the ferroelectric material doped with calcium, lanthanum, manganese or bismuth. Further alternatively, the ferroelectric layer pattern 218 may include a metal oxide such as titanium oxide, tantalum oxide, aluminum oxide, zinc oxide or hafnium oxide, etc. For example, the ferroelectric layer pattern 218 includes PZT that contains zirconium and titanium by a weight ratio of about 25:75 to about 40:60. The ferroelectric layer pattern 218 may have a thickness of about 200 to about 1,000 Å.

The upper electrode 227 includes a first upper electrode layer pattern 221 and a second upper electrode layer pattern 224 sequentially formed on the ferroelectric layer pattern 218. The upper electrode 227 is smaller than the ferroelectric layer pattern 218. As described above, the upper electrode 227 has a sidewall inclined by a predetermined angle with respect to the horizontal direction parallel to the substrate 173. For example, the sidewall of the upper electrode 227 is inclined by an angle of about 50 to about 80° relative to the horizontal direction. Similarly, the upper electrode 227 may also have a general pyramid (or mesa) structure. Accordingly, the ferroelectric structure 170 including the lower electrode 215, the ferroelectric layer pattern 218 and the upper electrode 227 has a sidewall inclined by an angle of about 50 to about 80° with respect to the horizontal direction parallel to the substrate 173.

The first upper electrode layer pattern 221 is smaller than the ferroelectric layer pattern 218. The first upper electrode layer pattern 221 may include a first metal oxide doped with a second metal. The second metal may include copper, lead or bismuth, and the first metal oxide may include SRO, STO, LNO or CRO. The second metal may be doped in the first metal oxide by a concentration of about 2 to about 5 atomic weight percent based on an entire atomic weight of the first metal oxide. For example, the first upper electrode layer pattern 221 include SRO doped with copper, lead or bismuth by a concentration of about 2 to about 5 atomic weight percent based on an entire atomic weight of SRO. The first upper electrode layer pattern 221 may have a thickness of about 10 to about 300 Å.

The second upper electrode layer pattern 224 is smaller than the first upper electrode layer pattern 221. The second upper electrode layer pattern 224 may have a thickness of about 300 to about 1,000 Å. The second upper electrode layer pattern 224 may include a third metal such as iridium, ruthenium, platinum, palladium or gold. For example, the second upper electrode layer pattern 224 includes iridium. As described above, the first metal in the second lower electrode layer pattern 212 may be substantially identical to the third metal in the second upper electrode layer pattern 224. Alternatively, the first metal in the second lower electrode layer pattern 212 may be different from the third metal in the second upper electrode layer pattern 224.

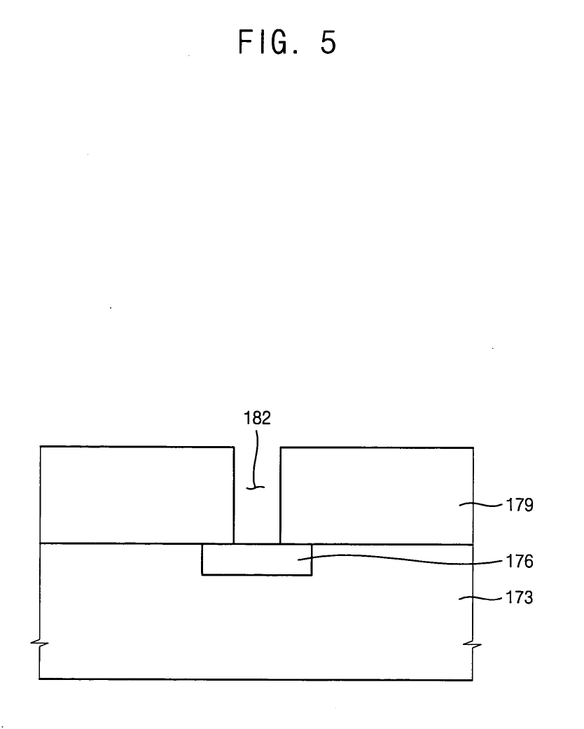

FIGS. 5 to 8 are cross-sectional views illustrating methods of forming the ferroelectric capacitors illustrated by FIG. 4. Referring to FIG. 5, a conductive structure 176 is formed on a substrate 173 such as a silicon wafer or an SOI substrate. The conductive structure 176 may include a contact region, a pad, a plug, a transistor, a conductive wiring or a conductive pattern formed on the substrate 173.

An insulation layer 179 is formed on the substrate 173 to cover the conductive structure 176. The insulation layer 179 may be formed on the substrate 173 by a CVD process, a plasma enhanced chemical vapor deposition (PECVD) process, or an HDP-CVD process. For example, the insulation layer 179 is formed using PSG, BPSG, USG, SOG, FOX, PE-TEOS, HDP-CVD oxide, etc.

After a photoresist pattern (not shown) is formed on the insulation layer 179, the insulation layer 179 is partially etched using the photoresist pattern as an etching mask, thereby forming a hole 182 through the insulation layer 179. The hole 182 partially exposes the conductive structure 176 formed on the substrate 173.

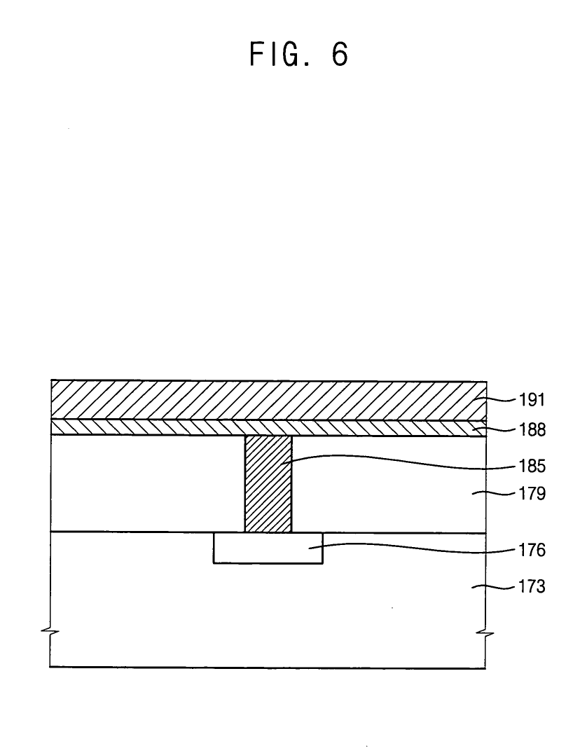

Referring to FIG. 6, a conductive layer is formed on the insulation layer 179 to fill up the hole 182. The conductive layer may include a metal or a conductive metal nitride such as tungsten, aluminum, copper, titanium, tungsten nitride, aluminum nitride, titanium nitride, etc. The conductive layer may be formed on the insulation layer 179 by a sputtering process, a CVD process or an ALD process.

An upper portion of the conductive layer is removed by a chemical mechanical polishing (CMP) process, an etch back process or a combination process of CMP and etch back until the insulation layer 179 is exposed. Hence, a pad 185 or a contact filling up the hole 182 is formed on the exposed conductive structure 176 through the insulation layer 179.

A first lower electrode layer 188& is formed on the pad 185 and the insulation layer 179. The first lower electrode layer 188 may be formed by a CVD process, a sputtering process or an ALD process using a metal nitride such as titanium aluminum nitride, aluminum nitride, titanium nitride, titanium silicon nitride, tantalum nitride, tantalum silicon nitride, etc. For example, the first lower electrode layer 188 is formed using titanium nitride by the ALD process. The first lower electrode layer 188 may be formed on the pad 185 and the insulation layer 179 to have a thickness of about 50 to about 300 Å.

Before forming the first lower electrode layer 188, an adhesion layer may be formed on the pad 185 and the insulation layer 179 by a CVD process, a sputtering process or an ALD process. The adhesion layer may include titanium, tantalum, aluminum, tungsten, titanium nitride, tantalum nitride, aluminum nitride, tungsten nitride, etc. Here, the first lower electrode layer 188 may be formed on the adhesion layer. The adhesion layer may improve an adhesion strength between the insulation layer 179 and the first lower electrode layer 188.

A second lower electrode layer 191 is formed on the first lower electrode layer 188. The second lower electrode layer 191 may be formed using a first metal such as iridium, ruthenium, platinum, palladium or gold by a sputtering process, a PLD process or an ALD process. For example, the second lower electrode layer 191 is formed using iridium by the sputtering process. The second lower electrode layer 191 may have a thickness of about 300 to about 1,000 Å.

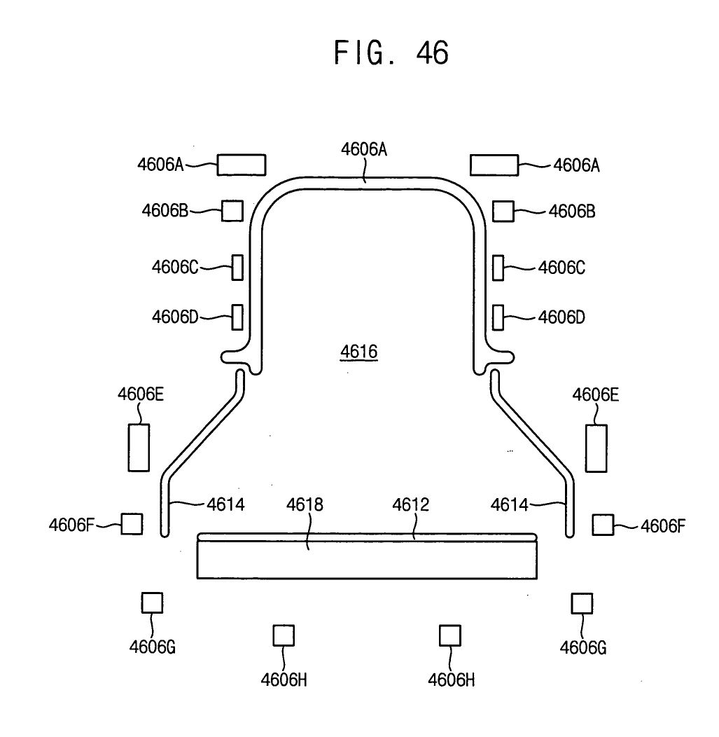

As will be appreciated by those skilled in the art given the benefit of the disclosure, a schematic illustration of a conventional sputtering apparatus 4600 is shown in FIG. 46. In particular, the sputtering apparatus 4600 represents what is commonly referred to as a Hollow Cathode Magnetron (HCM) sputtering apparatus. Referring to FIG. 46, the HCM sputtering apparatus 4600 includes a “cupped” target 4602 surrounded by electromagnetic coils 4606A-4606H. Shields 4614 extend from the cupped target 4602 to a surface 4612 holding a substrate 4610 on which relatively thin metal layers can be deposited by the sputtering process.

In operation, a vacuum is established in the inner region 4616 between the cupped target 4602 and the substrate 4610. An ionizing gas (such as Argon) is admitted to the region 4616, which is ionized by a magnetic and electric field provided thereto. The ionized gas is accelerated toward the cupped target 4602, which causes a portion of the material that makes up the cupped target 4602 to be ejected outwardly. The ejected portion of the target is directed toward the substrate 4610 by fields (electric/magnetic) generated by the electromagnetic coils 4606A-H. Accordingly, the material ejected from the cupped target 4602 is deposited on the substrate 4610. Conventional HCM sputtering apparatuses are further discussed, for example, in U.S. Pat. No. 6,589,398, to Lu et al. entitled Pasting Method for Eliminating Flaking During Nitrite Sputtering, the contents of which are incorporated herein by reference in its entirety.

In a formation of the second lower electrode layer 191 (by sputtering), a reaction chamber in which the substrate 173 is loaded may have a temperature of about 20 to about 350° C. and a relatively low pressure of about 3 to about 10 mTorr. In addition, the second lower electrode layer 191 may be formed in the reaction chamber by applying a power of about 300 to about 1,000 W under an inactive (or inert) gas atmosphere. The inactive gas may include an argon (Ar) gas, a nitrogen (N₂) gas, a helium (He) gas or a mixture thereof. Preferably, the inactive gas includes the argon gas only with a flow rate of about 10 to about 100 sccm.

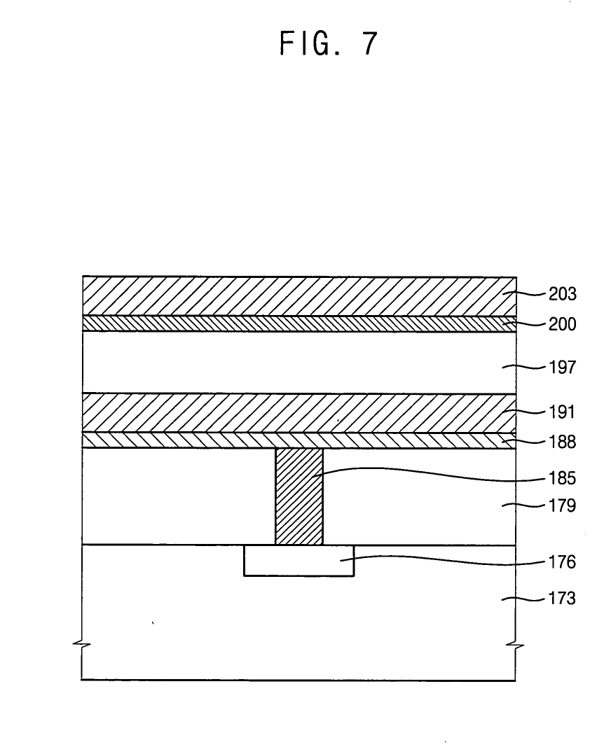

Referring to FIG. 7, a ferroelectric layer 197 is formed on the second lower electrode layer 191. The ferroelectric layer 197 may be formed by a metal organic chemical vapor deposition process, a sol-gel process or an ALD process. The ferroelectric layer 197 may be formed using a ferroelectric material such as PZT, SBT, BLT, PLZT or BST, or the ferroelectric material doped with calcium, lanthanum, manganese or bismuth. The ferroelectric layer 197 may be alternatively formed using a metal oxide such as titanium oxide, tantalum oxide, aluminum oxide, zinc oxide or hafnium oxide. For example, the ferroelectric layer 197 is formed using PZT that includes zirconium and titanium by a weight ratio of about 25:75 to about 40:60. The ferroelectric layer 197 may have a thickness of about 200 to about 1,000 Å.

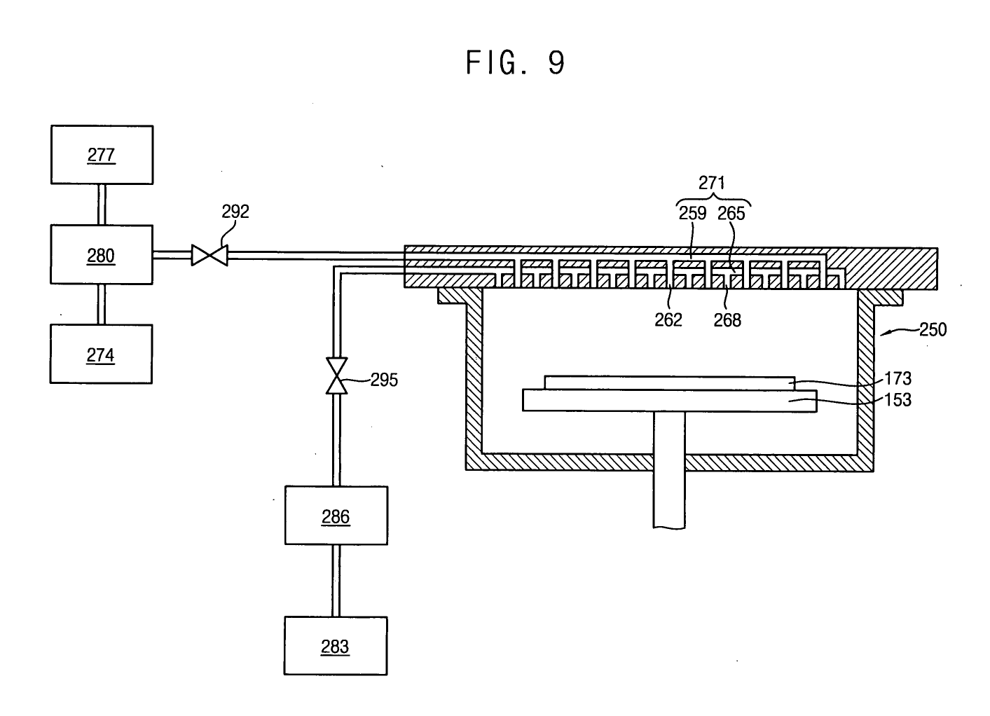

FIG. 9 is a schematic cross-sectional view illustrating the apparatus for the metal organic chemical vapor deposition (CVD) process. Referring to FIGS. 7 and 9, the substrate 173 including the second lower electrode layer 191 is placed on a susceptor 253 disposed in a reaction chamber 250. In the formation of the ferroelectric layer 197, the substrate 173 is maintained with a temperature of about 350 to about 650° C., and the reaction chamber 250 is maintained with a pressure of about 1 to about 10 Torr.

A showerhead 271 is disposed over the susceptor 253. The showerhead 271 includes a first spraying port 259 and a second spraying port 265 installed at an upper portion of the reaction chamber 250. The first spraying port 259 includes a plurality of first nozzles 262, and the second spraying port 265 also includes a plurality of second nozzles 268. The first and the second nozzles 262 and 268 may be alternately disposed over the susceptor 253.

A metal organic precursor is provided from a metal organic precursor source 274 into a vaporizer 280. The metal organic precursor is heated in the vaporizer 280. A carrier gas is provided from a carrier gas source 277 into the vaporizer 280 so that the carrier gas is also heated in the vaporizer 280. The metal organic precursor may include a first compound containing lead, a second compound containing zirconium, and a third compound containing titanium. The carrier gas may include a nitrogen gas, a helium gas or an argon gas. The heated metal organic precursor and the heated carrier gas are provided onto the substrate 173 through the first nozzles 262 of the first spraying port 259.

An oxidant is provided from an oxidant source 283 into a heater 286 so that the oxidant is heated in the heater 286. The heated oxidant is provided onto the substrate 173 through the second nozzles 268 of the second spraying port 265. The oxidant may include oxygen (O₂), ozone (O₃), nitrogen dioxide (NO₂) or nitrous oxide (N₂O). The heated metal organic precursor may have a temperature substantially identical to that of the heated oxidant.

In the formation of the ferroelectric layer 197 on the second lower electrode layer 191 by reacting the heated metal organic precursor with the heated oxidant, flow rates of the heated metal organic precursor and the heated oxidant may be controlled using a first valve 292 and a second valve 295. For example, the heated oxidant has a flow rate of about 1,000 to about 1,500 sccm. Therefore, the ferroelectric layer 197 is formed on the second lower electrode layer 191 to include PZT that contains zirconium and titanium by a weight ratio of about 25:75 to about 40:60.

Referring now to FIG. 7, a first upper electrode layer 200 is formed on the ferroelectric layer 197. The first upper electrode layer 200 may be formed by a sputtering process, a PLD process or an ALD process. The first upper electrode layer 200 may include a first metal oxide doped with a second metal by a concentration of about 2 to about 5 atomic weight percent based on an entire atomic weight of the first metal oxide. The first metal oxide may include SRO, STO, LNO or CRO, and the second metal may include copper, lead or bismuth. For example, the first upper electrode layer 200 is formed by the sputtering process using SRO doped with copper, lead or bismuth by a concentration of about 2 to about 5 atomic weight percent based on an entire atomic weight of SRO.

In a formation of the first upper electrode layer 200, the reaction chamber including the substrate 173 has a temperature of about 20 to about 350° C. and a relatively low pressure of about 3 to about 10 mTorr. The first upper electrode layer 200 may be formed in the reaction chamber by applying a power of about 300 to about 1,000 W under an inactive gas atmosphere. The inactive gas may include an argon gas, a nitrogen gas, a helium gas or a mixture thereof. For example, the inactive gas includes the argon gas only with a flow rate of about 10 to about 100 sccm. As a result, the first upper electrode layer 200 is formed on the ferroelectric layer 197 to have a thickness of about 10 to about 300 Å.

A second upper electrode layer 203 is formed on the first upper electrode layer 200. The second upper electrode layer 203 may be formed using a third metal such as iridium, ruthenium, platinum, palladium or gold. The second upper electrode layer 203 may be formed by a sputtering process, a PLD process or an ALD process. For example, the second upper electrode layer 203 is formed using iridium by the sputtering process. The second upper electrode layer 203 may have a thickness of about 300 to about 1,000 Å. As described above, the third metal in the second upper electrode layer 203 may be substantially identical to or different from the first metal in the second lower electrode layer 191.

In a formation of the second upper electrode layer 203, the reaction chamber including the substrate 173 therein may have a temperature of about 20 to about 350° C. and a relatively low pressure of about 3 to about 10 mTorr. The second upper electrode layer 203 may be formed in the reaction chamber by applying a power of about 300 to about 1,000 W under an inactive gas atmosphere. The inactive gas may include an argon gas, a nitrogen gas, a helium gas or a mixture thereof. For example, the second upper electrode layer 203 is formed under an inactive gas atmosphere including the argon gas only with a flow rate of about 10 to about 100 sccm.

After the second upper electrode layer 203 is formed, the substrate 173 including the ferroelectric layer 197 and the first upper electrode layer 200 is thermally treated to thereby crystallize ingredients in the ferroelectric layer 197 and the first upper electrode layer 200. The ferroelectric layer 197 and the first upper electrode layer 200 may be thermally treated by a RTP under an oxygen atmosphere, a nitrogen atmosphere or a mixture atmosphere including oxygen and nitrogen. The ferroelectric layer 197 and the first upper electrode layer 200 may be thermally treated at a temperature of about 500 to about 600° C. for about 30 seconds to about 3 minutes.

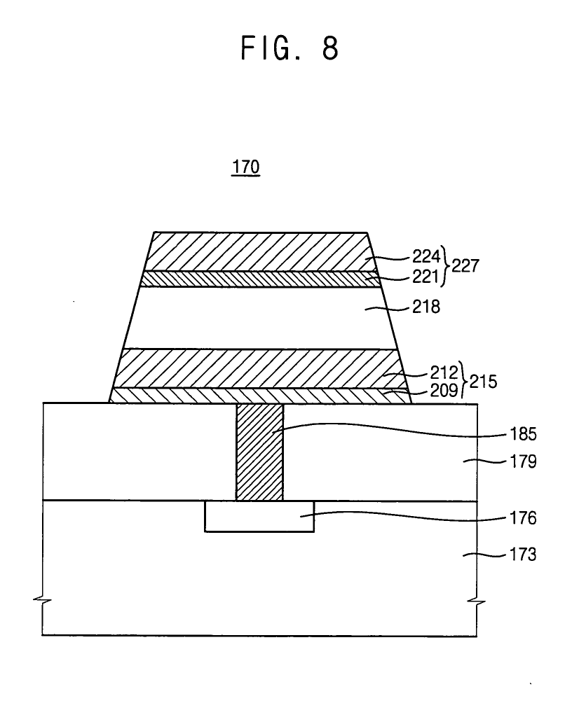

Referring to FIG. 8, a photoresist pattern (not shown) is formed on the second upper electrode layer 203. Using the photoresist pattern as an etching mask, the second upper electrode layer 203, the first upper electrode layer 200, the ferroelectric layer 197, the second lower electrode layer 191 and the first lower electrode layer 188 are sequentially etched, thereby forming the ferroelectric capacitor 170 including the lower electrode 215, the ferroelectric layer pattern 218 and the upper electrode 227 over the substrate 173 as shown in FIG. 4. The lower electrode 215 includes a first lower electrode layer pattern 209 and a second lower electrode layer pattern 212 sequentially formed on the pad 185 and the insulation layer 179. The upper electrode 227 includes a first upper electrode layer pattern 221 and a second upper electrode layer pattern 224 successively formed on the ferroelectric layer pattern 218. Due to the above etching process, the ferroelectric capacitor 170 has a sidewall inclined by an angle of about 50 to about 80° relative to a horizontal direction. Thus, the ferroelectric capacitor 170 may generally have a pyramid (or mesa) shape.

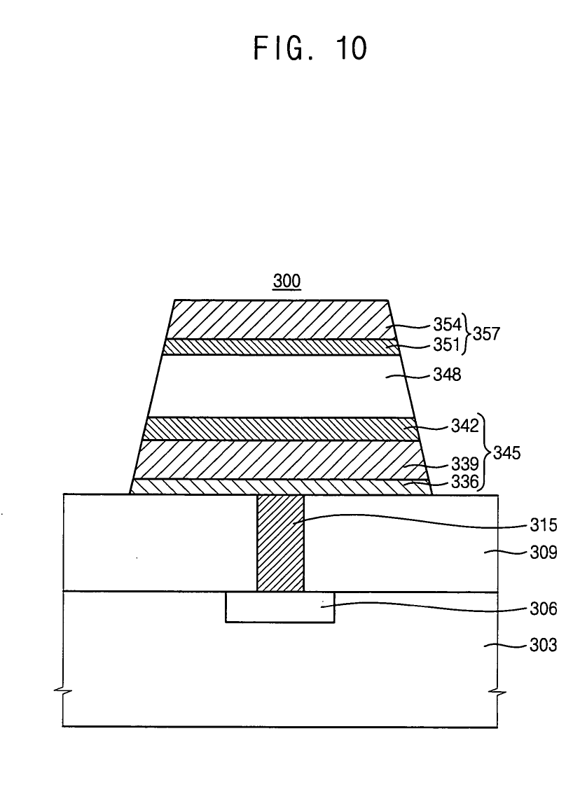

FIG. 10 is a cross-sectional view illustrating ferroelectric capacitors in accordance with some exemplary embodiments of the present invention. Referring to FIG. 10, a ferroelectric capacitor 300 includes a lower electrode 345 formed on an insulation layer 309, a ferroelectric layer pattern 348 formed on the lower electrode 345, and an upper electrode 357 formed on the ferroelectric layer pattern 348. The lower electrode 345 includes a first lower electrode layer pattern 336, a second lower electrode layer pattern 339 and a third lower electrode layer pattern 342 sequentially formed on a pad 315 and the insulation layer 309. The upper electrode 357 includes a first upper electrode layer pattern 351 and a second upper electrode layer pattern 354 successively formed on the ferroelectric layer pattern 348.

The second lower electrode layer pattern 336 may include a first metal, and the first upper electrode layer pattern 351 may include a first metal oxide doped with a second metal. The second upper electrode layer pattern 354 may include a third metal, and the third lower electrode layer pattern 342 may include a second metal oxide doped with a fourth metal. The first metal may be substantially identical to or different from the third metal. Each of the first metal and the third metal may correspond to iridium, platinum, ruthenium, palladium or gold. The first metal oxide may be substantially identical to or different from the second metal oxide, and also the second metal may be substantially identical to or different from the fourth metal. Each of the first metal oxide and the second metal oxide may correspond to SRO, STO, LNO or CRO, and each of the second metal and the fourth metal may correspond to copper, lead or bismuth.

The insulation layer 309 is formed on a substrate 303 including a conductive structure 306 such as a contact region, a pad, a plug, a transistor, a conductive pattern, a conductive wiring, etc. The insulation layer 309 may include BPSG, PSG, USG, SOG, FOX, PE-TEOS, HDP-CVD oxide, etc.

A pad 315 or a plug is formed through the insulation layer 345. The pad 315 contacts the conductive structure 306 to thereby electrically connect the lower electrode 345 to the conductive structure 306. The pad 315 may include a metal or a conductive metal nitride such as tungsten, aluminum, copper, titanium, tungsten nitride, aluminum nitride, titanium nitride, etc.

The first lower electrode layer pattern 336 may reduce diffusion of oxygen atoms from the ferroelectric layer pattern 348. The second and the third lower electrode layer patterns 339 and 342 improve together a crystallization of ingredients contained in the ferroelectric layer pattern 348. In addition, the first lower electrode layer pattern 336 enhances an adhesive strength between the insulation layer 309 and the second lower electrode layer pattern 339 when an adhesion layer is not formed on the insulation layer 309 and the pad 315.

As described above, the lower electrode 345 has a sidewall inclined by an angle of about 50 to about 80° relative to a horizontal direction parallel to the substrate 303. The first lower electrode layer pattern 336 may include a metal nitride such as titanium aluminum nitride, aluminum nitride, titanium nitride, titanium silicon nitride, tantalum nitride, tungsten nitride, tantalum silicon nitride, etc. The first lower electrode layer pattern 336 may have a thickness of about 50 to about 300 Å from an upper face of the insulation layer 309.

The second lower electrode layer pattern 339 may include a first metal such as iridium, ruthenium, platinum, palladium or gold. The second lower electrode layer pattern 339 may have a thickness of about 300 to about 1,000 Å based on an upper face of the first lower electrode layer pattern 336. The second lower electrode layer pattern 339 is smaller than that of the first lower electrode layer pattern 336.

The third lower electrode layer pattern 342 may include a second metal oxide doped with a fourth metal by a concentration of about 2 to about 5 atomic weight percent based on an entire atomic weight of the second metal oxide. The second metal oxide may include SRO, STO, LNO or CRO, and the fourth metal may include copper, lead or bismuth. The third lower electrode layer pattern 342 may have a thickness of about 10 to about 500 Å from an upper face of the second lower electrode layer pattern 339. The third lower electrode layer pattern 342 is smaller than the second lower electrode layer pattern 339. Thus, the lower electrode 345 including the first to the third lower electrode layer patterns 336, 339 and 342 generally has a pyramid (or mesa) structure.

The ferroelectric layer pattern 348 is formed on the third lower electrode layer pattern 342. The ferroelectric layer pattern 348 may have a size substantially smaller than that of the third lower electrode layer pattern 342. As the sidewall of the lower electrode 345, the ferroelectric layer pattern 348 also has a sidewall inclined by an angle of about 50 to about 80° with respect to the horizontal direction parallel to the substrate 303. The ferroelectric layer pattern 348 may include a ferroelectric material such as PZT, SBT, BLT, PLZT, BST, etc. Alternatively, the ferroelectric layer pattern 348 may include the ferroelectric material doped with calcium, lanthanum, manganese or bismuth, or a metal oxide such as titanium oxide, tantalum oxide, aluminum oxide, zinc oxide or hafnium oxide, etc. The ferroelectric layer pattern 348 may have a thickness of about 200 to about 1,000 Å from an upper face of the third lower electrode layer pattern 342.

The upper electrode 357 is smaller than the ferroelectric layer pattern 348. As described above, the upper electrode 357 has a sidewall inclined by an angle of about 50 to about 80° with respect to the horizontal direction parallel to the substrate 303. Accordingly, the ferroelectric structure 300 including the lower electrode 345, the ferroelectric layer pattern 348 and the upper electrode 357 has a sidewall inclined by an angle of about 50 to about 80° with respect to the horizontal direction parallel to the substrate 303. Hence, the ferroelectric structure 300 may have a general pyramid (or mesa) shape.

The first upper electrode layer pattern 351 is smaller than the ferroelectric layer pattern 348. The first upper electrode layer pattern 351 may include a first metal oxide doped with a second metal a concentration of about 2 to about 5 atomic weight percent based on an entire atomic weight of the first metal oxide. The second metal may include copper, lead or bismuth, and the first metal oxide may include SRO, STO, LNO or CRO. The first upper electrode layer pattern 351 may have a thickness of about 10 to about 300 Å based on an upper face of the ferroelectric layer pattern 348.

The second upper electrode layer pattern 354 is smaller than the first upper electrode layer pattern 351. The second upper electrode layer pattern 354 may have a thickness of about 300 to about 1,000 Å from an upper face of the first upper electrode layer pattern 351. The second upper electrode layer pattern 354 may include a third metal such as iridium, ruthenium, platinum, palladium or gold.

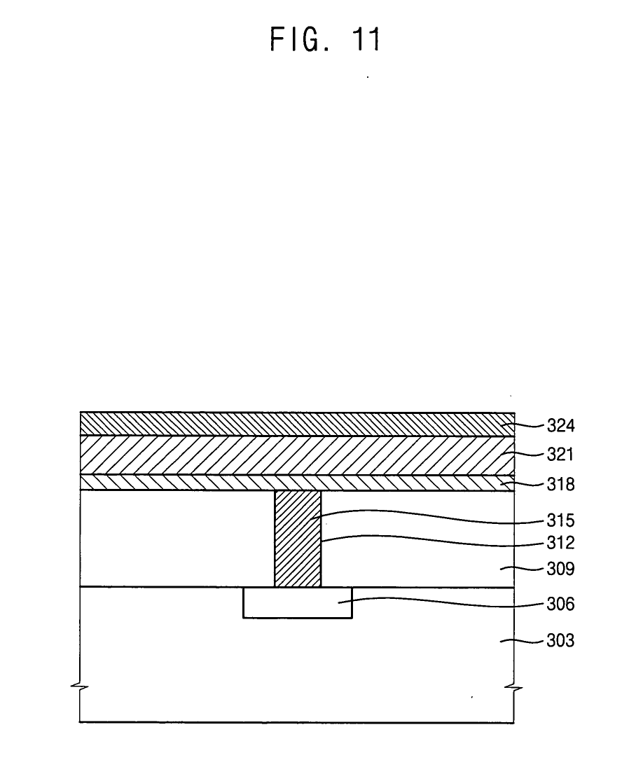

FIGS. 11 to 13 are cross-sectional views illustrating methods of forming the ferroelectric capacitors illustrated by FIG. 10. Referring to FIG. 11, a conductive structure 306 is formed on a semiconductor substrate 303 such as a silicon wafer or an SOI substrate. The conductive structure 306 may include a contact region, a pad, a plug, a transistor, a conductive wiring, a conductive pattern, etc.

An insulation layer 309 is formed on the substrate 303 to cover the conductive structure 306. The insulation layer 309 covering the conductive structure 306 may be formed by a CVD process, a PECVD process or an HDP-CVD process. The insulation layer 309 may be formed using PSG, BPSG, USG, SOG, FOX, PE-TEOS, HDP-CVD oxide, etc.

After a photoresist pattern (not shown) is formed on the insulation layer 309, a portion of the insulation layer 309 is etched using the photoresist pattern as an etching mask, thereby forming a hole 312 exposing the conductive structure 306 through the insulation layer 309.

A conductive layer is formed on the insulation layer 309 to fill up the hole 312. The conductive layer may be formed using a metal or a conductive metal nitride such as tungsten, aluminum, copper, titanium, tungsten nitride, aluminum nitride, titanium nitride, etc. The conductive layer may be formed on the insulation layer 309 by a sputtering process, a CVD process or an ALD process.

The conductive layer is partially removed by a CMP process, an etch back process or a combination process of CMP and etch back until the insulation layer 309 is exposed, thereby forming a pad 315 or a contact filling up the hole 312 on the exposed conductive structure 306 through the insulation layer 309.

A first lower electrode layer 318 is formed on the pad 315 and the insulation layer 309. The first lower electrode layer 318 may be formed by a CVD process, a sputtering process or an ALD process using a metal nitride such as titanium aluminum nitride, aluminum nitride, titanium nitride, titanium silicon nitride, tantalum nitride, tantalum silicon nitride, etc. The first lower electrode layer 318 may have a thickness of about 50 to about 300 Å.

As described above, an adhesion layer may be formed between the insulation layer 309 and the first lower electrode layer 318 by a CVD process, a sputtering process or an ALD process. The adhesion layer may be formed using a metal or a metal nitride such as titanium, tantalum, aluminum, tungsten, titanium nitride, tantalum nitride, aluminum nitride, tungsten nitride, etc.

A second lower electrode layer 321 is formed on the first lower electrode layer 318 to have a thickness of about 300 to about 1,000 Å. The second lower electrode layer 321 may be formed using a first metal such as iridium, ruthenium, platinum, palladium or gold by a sputtering process, a PLD process or an ALD process. In some embodiments according to the invention, the second lower electrode layer 321 can be formed in a reaction chamber in which the substrate 303 is loaded. The reaction chamber may be maintained at a temperature of about 20 to about 350° C. and a relatively low pressure of about 3 to about 10 mTorr. The second lower electrode layer 321 may be formed in the reaction chamber by applying a power of about 300 to about 1,000 W under an inactive gas atmosphere including an argon gas, a nitrogen gas, a helium gas or a mixture thereof. Here, the inactive gas includes the argon gas only with a flow rate of about 10 to about 100 sccm.

A third lower electrode layer 324 is formed on the second lower electrode layer 321 to have a thickness of about 10 to about 500 Å. The third lower electrode layer 324 may be formed using a second metal oxide doped with a fourth metal by a concentration of about 2 to about 5 atomic weight percent based on an entire atomic weight of the second metal oxide. For example, the third lower electrode layer 324 may be formed using a sputtering target of SRO, STO, LNO or CRO doped with copper, lead or bismuth. In some embodiments according to the invention, the third lower electrode layer 324 can be formed in the reaction chamber in which the substrate 303 is loaded. The chamber may be maintained at a temperature of about 20 to about 600° C. and a relatively low pressure of about 3 to about 10 mTorr. The third lower electrode layer 324 may be formed in the reaction chamber by applying a power of about 300 to about 1,000 W under an inactive gas atmosphere including an argon gas, a nitrogen gas, a helium gas or a mixture thereof. Here, the inactive gas includes the argon gas only with a flow rate of about 10 to about 100 sccm.

Referring to FIG. 12, a ferroelectric layer 327 is formed on the third lower electrode layer 324 to have a thickness of about 200 to about 1,000 Å. The ferroelectric layer 327 may be formed on the third lower electrode layer 324 by a metal organic chemical vapor deposition process, a sol-gel process or an ALD process. The ferroelectric layer 327 may be formed using a ferroelectric material such as PZT, SBT, BLT, PLZT or BST, or the ferroelectric material doped with calcium, lanthanum, manganese or bismuth. The ferroelectric layer 327 may be alternatively formed using a metal oxide such as titanium oxide, tantalum oxide, aluminum oxide, zinc oxide or hafnium oxide. For example, the ferroelectric layer 327 is formed on the third lower electrode layer 324 using an apparatus and processes substantially identical to those described with FIG. 9. Therefore, the ferroelectric layer 327 may include PZT that contains zirconium and titanium by a weight ratio of about 25:75 to about 40:60.

A first upper electrode layer 330 is formed on the ferroelectric layer 327 to have a thickness of about 10 to about 300 Å. The first upper electrode layer 330 may be formed on the ferroelectric layer 327 by a sputtering process, a PLD process or an ALD process. The first upper electrode layer 330 may include a first metal oxide doped with a second metal by a concentration of about 2 to about 5 atomic weight percent based on an entire atomic weight of the first metal oxide. For example, the first upper electrode layer 330 includes SRO, STO, LNO or CRO doped with copper, lead or bismuth. In a formation of the first upper electrode layer 330, the reaction chamber including the substrate 303 has a temperature of about 20 to about 350° C. and a relatively low pressure of about 3 to about 10 mTorr. Here, the first upper electrode layer 330 may be formed in the reaction chamber by applying a power of about 300 to about 1,000 W under an inactive gas atmosphere including an argon gas, a nitrogen gas, a helium gas or a mixture thereof. For example, the inactive gas includes the argon gas only with a flow rate of about 10 to about 100 sccm.

A second upper electrode layer 333 is formed on the first upper electrode layer 330 to have a thickness of about 300 to about 1,000 Å. The second upper electrode layer 333 may be formed using a third metal such as iridium, ruthenium, platinum, palladium or gold. The second upper electrode layer 333 may be formed on the first upper electrode layer 330 by a sputtering process, a PLD process or an ALD process. As described above, the third metal in the second upper electrode layer 333 may be substantially identical to or different from the first metal in the second lower electrode layer 321. In a formation of the second upper electrode layer 333, the reaction chamber including the substrate 303 therein may have a temperature of about 20 to about 350° C. and a relatively low pressure of about 3 to about 10 mTorr. The second upper electrode layer 333 may be formed in the reaction chamber by applying a power of about 300 to about 1,000 W under an inactive gas atmosphere that includes an argon gas, a nitrogen gas, a helium gas or a mixture thereof. For example, the second upper electrode layer 333 is formed under an inactive gas atmosphere including the argon gas only with a flow rate of about 10 to about 100 sccm.

After the second upper electrode layer 333 is formed on the first upper electrode layer 330, the substrate 303 including the ferroelectric layer 327 and the first upper electrode layer 330 is thermally treated to thereby crystallize ingredients in the ferroelectric layer 327 and the first upper electrode layer 330. The ferroelectric layer 327 and the first upper electrode layer 200 may be thermally treated by a rapid thermal anneal (RTP) under an oxygen atmosphere, a nitrogen atmosphere or a mixture atmosphere including oxygen and nitrogen. The ferroelectric layer 327 and the first upper electrode layer 330 may be thermally treated at a temperature of about 500 to about 600° C. for about 30 seconds to about 3 minutes.

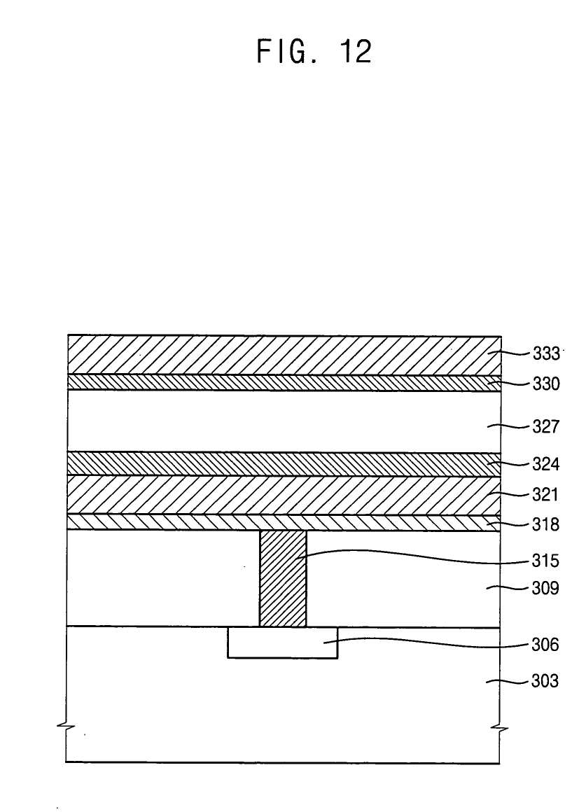

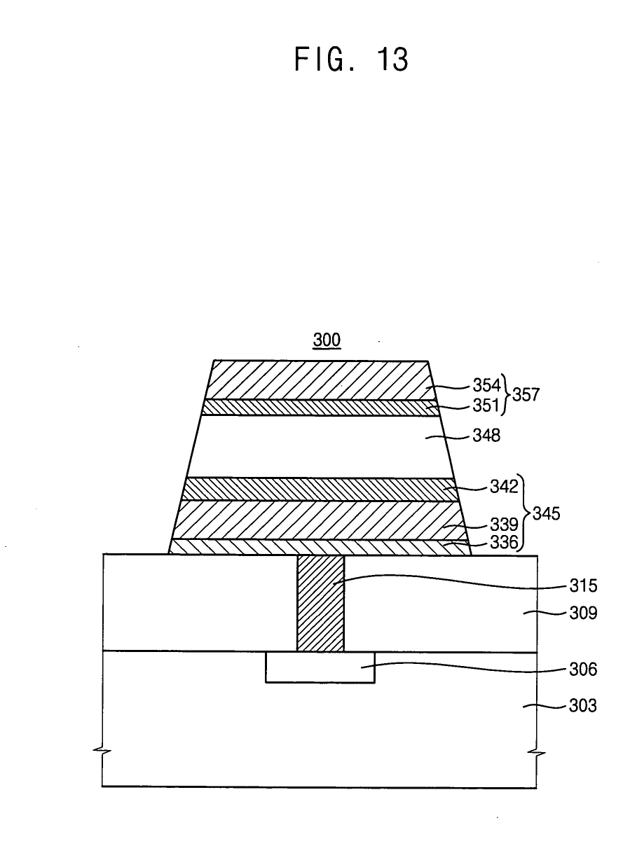

Referring to FIG. 13, after a photoresist pattern (not shown) is formed on the second upper electrode layer 303, the second and the first upper electrode layers 303 and 330, the ferroelectric layer 237, and the third to the first lower electrode layers 324, 321 and 318 are sequentially etched using the photoresist pattern as an etching mask. Thus, the ferroelectric capacitor 300 is formed over the semiconductor substrate 303 as shown in FIG. 10. The ferroelectric capacitor 300 includes the lower electrode 345, the ferroelectric layer pattern 348 and the upper electrode 357. The lower electrode 345 includes a first lower electrode layer pattern 336, a second lower electrode layer pattern 339 and a third lower electrode layer pattern 342 sequentially formed on the pad 315 and the insulation layer 309. The upper electrode 357 includes a first upper electrode layer pattern 351 and a second upper electrode layer pattern 354 successively formed on the ferroelectric layer pattern 348. After the above etching process, the ferroelectric capacitor 300 has a sidewall inclined by an angle of about 50 to about 80° relative to the horizontal direction.

Hereinafter, there will be described the characteristics of ferroelectric capacitors in accordance with various Examples and Comparative Example 1 of the present invention.

### EXAMPLE 1

After a first lower electrode layer pattern including titanium aluminum nitride was formed, a second lower electrode layer pattern including iridium was formed on the first lower electrode layer pattern. The first lower electrode layer pattern had a thickness of about 50 521 , and the second lower electrode layer pattern had a thickness of about 300 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

A first upper electrode layer pattern was formed on the ferroelectric layer pattern. The first upper electrode layer pattern was formed using strontium ruthenium oxide doped with copper by a concentration of about 3 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 300 W. The first upper electrode layer pattern had a thickness of about 50 Å, and the second upper electrode layer pattern had a thickness of about 600 Å.

The ferroelectric layer pattern, the first upper electrode layer pattern and the second upper electrode layer pattern were thermally treated by a rapid thermal process at a temperature of about 550° C. for about 1 minute.

### EXAMPLE 2

After a first lower electrode layer pattern including titanium aluminum nitride was formed, a second lower electrode layer pattern including iridium was formed on the first lower electrode layer pattern. The first lower electrode layer pattern had a thickness of about 50 Å, and the second lower electrode layer pattern had a thickness of about 300 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

A first upper electrode layer pattern was formed on the ferroelectric layer pattern. The first upper electrode layer pattern was formed using strontium ruthenium oxide doped with lead by a concentration of about 3 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 300 W. The first upper electrode layer pattern had a thickness of about 50 Å, and the second upper electrode layer pattern had a thickness of about 600 Å.

The ferroelectric layer pattern, the first upper electrode layer pattern and the second upper electrode layer pattern were thermally treated by a rapid thermal process at a temperature of about 600° C. for about 1 minute.

### EXAMPLE 3

After a first lower electrode layer pattern including titanium aluminum nitride was formed, a second lower electrode layer pattern including iridium was formed on the first lower electrode layer pattern. The first lower electrode layer pattern had a thickness of about 100 Å, and the second lower electrode layer pattern had a thickness of about 400 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,100 Å.

A first upper electrode layer pattern was formed on the ferroelectric layer pattern. The first upper electrode layer pattern was formed using strontium ruthenium oxide doped with bismuth by a concentration of about 3 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 300 W. The first upper electrode layer pattern had a thickness of about 100 Å, and the second upper electrode layer pattern had a thickness of about 500 Å.

The ferroelectric layer pattern, the first upper electrode layer pattern and the second upper electrode layer pattern were thermally treated by a rapid thermal process at a temperature of about 550° C. for about 1 minute.

### EXAMPLE 4

After a first lower electrode layer pattern including titanium aluminum nitride was formed, a second lower electrode layer pattern including iridium was formed on the first lower electrode layer pattern. The first lower electrode layer pattern had a thickness of about 100 Å, and the second lower electrode layer pattern had a thickness of about 400 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,100 Å.

A first upper electrode layer pattern was formed on the ferroelectric layer pattern. The first upper electrode layer pattern was formed using strontium ruthenium oxide doped with bismuth by a concentration of about 3 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 300 W. The first upper electrode layer pattern had a thickness of about 100 Å, and the second upper electrode layer pattern had a thickness of about 500 Å.

The ferroelectric layer pattern, the first upper electrode layer pattern and the second upper electrode layer pattern were thermally treated by a rapid thermal process at a temperature of about 600° C. for about 1 minute.

### EXAMPLE 5

After a first lower electrode layer pattern including titanium aluminum nitride was formed, a second lower electrode layer pattern including iridium was formed on the first lower electrode layer pattern. The first lower electrode layer pattern had a thickness of about 50 Å, and the second lower electrode layer pattern had a thickness of about 600 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

A first upper electrode layer pattern was formed on the ferroelectric layer pattern. The first upper electrode layer pattern was formed using strontium ruthenium oxide doped with lead by a concentration of about 5 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 300 W. The first upper electrode layer pattern had a thickness of about 50 Å, and the second upper electrode layer pattern had a thickness of about 600 Å.

The ferroelectric layer pattern, the first upper electrode layer pattern and the second upper electrode layer pattern were thermally treated by a rapid thermal process at a temperature of about 600° C. for about 1 minute.

### EXAMPLE 6

After a first lower electrode layer pattern including titanium aluminum nitride was formed, a second lower electrode layer pattern including iridium was formed on the first lower electrode layer pattern. The first lower electrode layer pattern had a thickness of about 150 Å, and the second lower electrode layer pattern had a thickness of about 500 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

A first upper electrode layer pattern was formed on the ferroelectric layer pattern. The first upper electrode layer pattern was formed using strontium ruthenium oxide doped with bismuth by a concentration of about 3 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 300 W. The first upper electrode layer pattern had a thickness of about 100 Å, and the second upper electrode layer pattern had a thickness of about 500 Å.

The ferroelectric layer pattern, the first upper electrode layer pattern and the second upper electrode layer pattern were thermally treated by a rapid thermal process at a temperature of about 600° C. for about 1 minute.

### EXAMPLE 7

After a first lower electrode layer pattern including titanium aluminum nitride was formed, a second lower electrode layer pattern including iridium was formed on the first lower electrode layer pattern. The first lower electrode layer pattern had a thickness of about 50 Å, and the second lower electrode layer pattern had a thickness of about 600 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 600 Å.

A first upper electrode layer pattern was formed on the ferroelectric layer pattern. The first upper electrode layer pattern was formed using strontium ruthenium oxide doped with copper by a concentration of about 4 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 600 W. The first upper electrode layer pattern had a thickness of about 50 Å, and the second upper electrode layer pattern had a thickness of about 600 Å.

The ferroelectric layer pattern, the first upper electrode layer pattern and the second upper electrode layer pattern were thermally treated by a rapid thermal process at a temperature of about 600° C. for about 1 minute.

### EXAMPLE 8

After a first lower electrode layer pattern including titanium aluminum nitride was formed, a second lower electrode layer pattern including iridium was formed on the first lower electrode layer pattern. The first lower electrode layer pattern had a thickness of about 150 Å, and the second lower electrode layer pattern had a thickness of about 500 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,100 Å.

A first upper electrode layer pattern was formed on the ferroelectric layer pattern. The first upper electrode layer pattern was formed using strontium ruthenium oxide doped with lead by a concentration of about 4 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 600 W. The first upper electrode layer pattern had a thickness of about 100 Å, and the second upper electrode layer pattern had a thickness of about 500 Å.

The ferroelectric layer pattern, the first upper electrode layer pattern and the second upper electrode layer pattern were thermally treated by a rapid thermal process at a temperature of about 600° C. for about 1 minute.

### EXAMPLE 9

After a first lower electrode layer pattern including titanium aluminum nitride was formed, a second lower electrode layer pattern including iridium was formed on the first lower electrode layer pattern. The first lower electrode layer pattern had a thickness of about 50 Å, and the second lower electrode layer pattern had a thickness of about 600 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 500 Å.

A first upper electrode layer pattern was formed on the ferroelectric layer pattern. The first upper electrode layer pattern was formed using strontium ruthenium oxide doped with copper by a concentration of about 4 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 1,000 W. The first upper electrode layer pattern had a thickness of about 50 Å, and the second upper electrode layer pattern had a thickness of about 600 Å.

The ferroelectric layer pattern, the first upper electrode layer pattern and the second upper electrode layer pattern were thermally treated by a rapid thermal process at a temperature of about 600° C. for about 1 minute.

### EXAMPLE 10

After a first lower electrode layer pattern including titanium aluminum nitride was formed, a second lower electrode layer pattern including iridium was formed on the first lower electrode layer pattern. The first lower electrode layer pattern had a thickness of about 100 Å, and the second lower electrode layer pattern had a thickness of about 500 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,100 Å.

A first upper electrode layer pattern was formed on the ferroelectric layer pattern. The first upper electrode layer pattern was formed using strontium ruthenium oxide doped with bismuth by a concentration of about 4 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 1,000 W. The first upper electrode layer pattern had a thickness of about 100 Å, and the second upper electrode layer pattern had a thickness of about 500 Å.

The ferroelectric layer pattern, the first upper electrode layer pattern and the second upper electrode layer pattern were thermally treated by a rapid thermal process at a temperature of about 600° C. for about 1 minute.

### EXAMPLE 11

After a first lower electrode layer pattern including titanium aluminum nitride was formed, a second lower electrode layer pattern including iridium was formed on the first lower electrode layer pattern. The first lower electrode layer pattern had a thickness of about 50 Å, and the second lower electrode layer pattern had a thickness of about 600 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

A first upper electrode layer pattern was formed on the ferroelectric layer pattern. The first upper electrode layer pattern was formed using strontium ruthenium oxide doped with bismuth by a concentration of about 4 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 1,000 W. The first upper electrode layer pattern had a thickness of about 50 Å, and the second upper electrode layer pattern had a thickness of about 600 Å.

The ferroelectric layer pattern, the first upper electrode layer pattern and the second upper electrode layer pattern were thermally treated by a rapid thermal process at a temperature of about 550° C. for about 1 minute.

### EXAMPLE 12

After a first lower electrode layer pattern including titanium aluminum nitride was formed, a second lower electrode layer pattern including iridium was formed on the first lower electrode layer pattern. The first lower electrode layer pattern had a thickness of about 100 Å, and the second lower electrode layer pattern had a thickness of about 600 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

A first upper electrode layer pattern was formed on the ferroelectric layer pattern. The first upper electrode layer pattern was formed using strontium ruthenium oxide doped with bismuth by a concentration of about 4 atomic weight percent based on an entire atomic weight of the strontium ruthenium oxide. Then, a second upper electrode layer pattern including iridium was formed on the first upper electrode layer pattern. Each of the first and the second upper electrode layer patterns was formed by applying a power of about 1,000 W. The first upper electrode layer pattern had a thickness of about 100 Å, and the second upper electrode layer pattern had a thickness of about 500 Å.

The ferroelectric layer pattern, the first upper electrode layer pattern and the second upper electrode layer pattern were thermally treated by a rapid thermal process at a temperature of about 600° C. for about 1 minute.

### COMPARATIVE EXAMPLE 1

After a first lower electrode layer pattern including titanium aluminum nitride was formed, a second lower electrode layer pattern including iridium was formed on the first lower electrode layer pattern. The first lower electrode layer pattern had a thickness of about 50 Å, and the second lower electrode layer pattern had a thickness of about 300 Å.

A ferroelectric layer pattern was formed on the second lower electrode layer pattern. The ferroelectric layer pattern was formed using PZT that included zirconium and titanium by a weight ratio of about 35:65. The ferroelectric layer pattern had a thickness of about 1,000 Å.

After a first upper electrode layer pattern including iridium oxide (IrO₂) was formed on the ferroelectric layer pattern, a second upper electrode layer pattern including iridium was formed on the first upper electrode layer pattern. Each of the first and the second upper electrode layer patterns was formed by applying a power of about 300 W. The first upper electrode layer pattern had a thickness of about 2,300 Å, and the second upper electrode layer pattern had a thickness of about 400 Å.

The ferroelectric layer pattern, the first upper electrode layer pattern and the second upper electrode layer pattern were thermally treated by a rapid thermal process at a temperature of about 600° C. for about 1 minute.

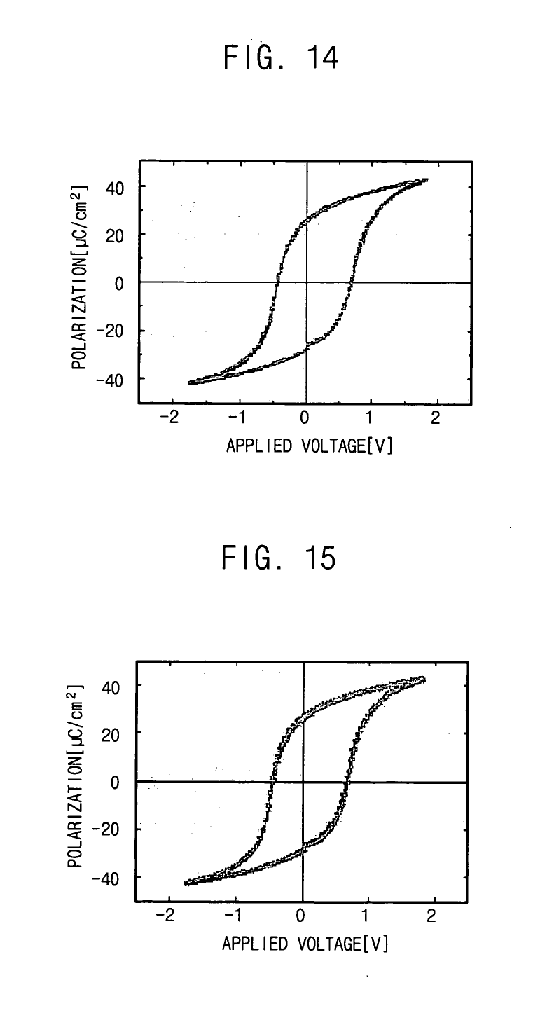

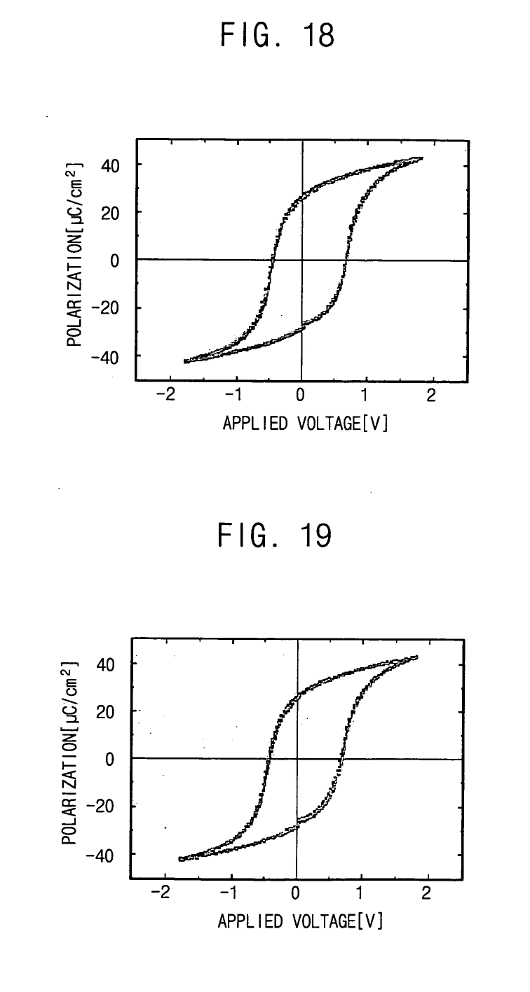

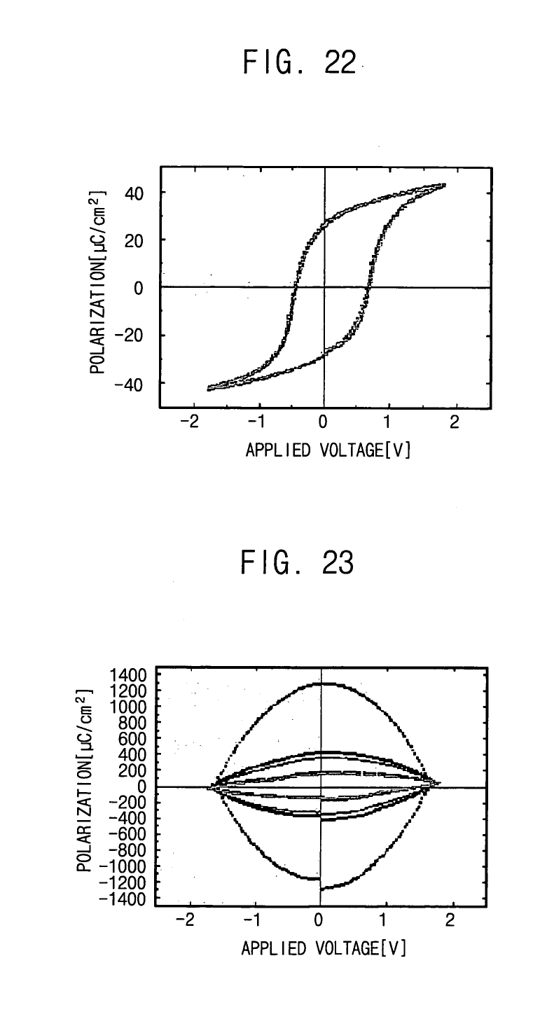

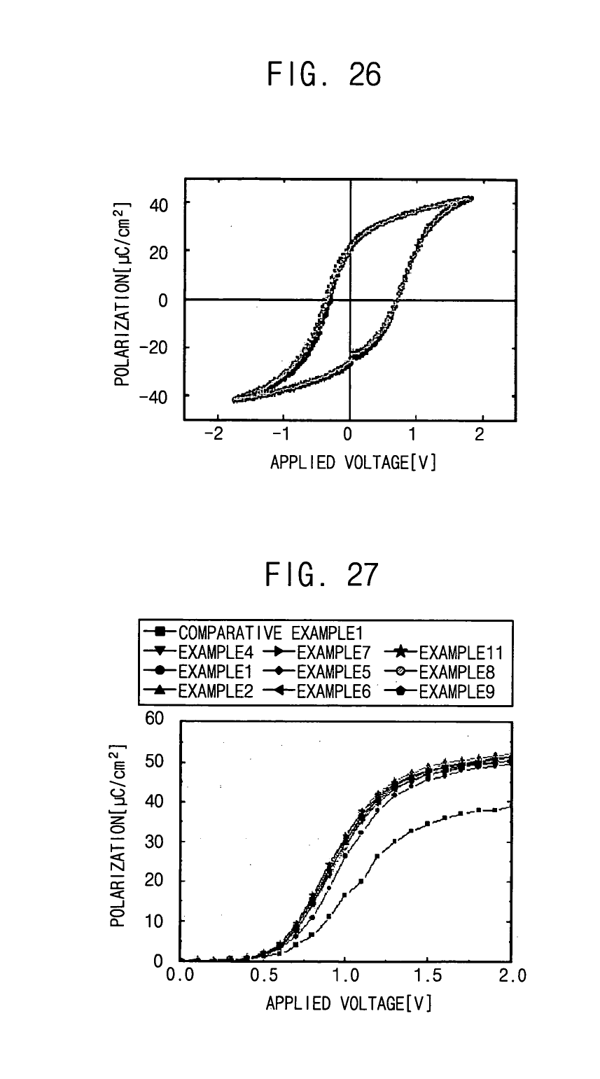

FIGS. 14 to 25 are graphs showing P-V (polarization-voltage) hysteresis loops of ferroelectric capacitors in accordance with Examples 1 to 12. FIG. 26 is a graph showing a P-V hysteresis loop of a ferroelectric capacitor in accordance with Comparative Example 1. In FIGS. 14 to 26, the hysteresis loops were obtained by measuring polarizations of ferroelectric layer patterns in the ferroelectric capacitors relative to applied voltages.

Referring to FIGS. 14 and 15, the ferroelectric capacitor of Example 1 had 2 Pr (polarization) of about 50.77 μC/cm² and −2 Pr of about −50.418 μC/cm². Here, +Vc was about 0.698V and −Vc was about −0.432V. In addition, the ferroelectric capacitor of Example 2 had 2 Pr of about 53.67 μC/cm² and −2 Pr of about −53.36 μC/cm². Here, +Vc was about 0.60V and −Vc was about −0.45V.

As shown in FIG. 16, however, the ferroelectric capacitor of Example 3 did not show a normal P-V hysteresis loop so that electrical characteristics of the ferroelectric capacitor of Example 3 were deteriorated.

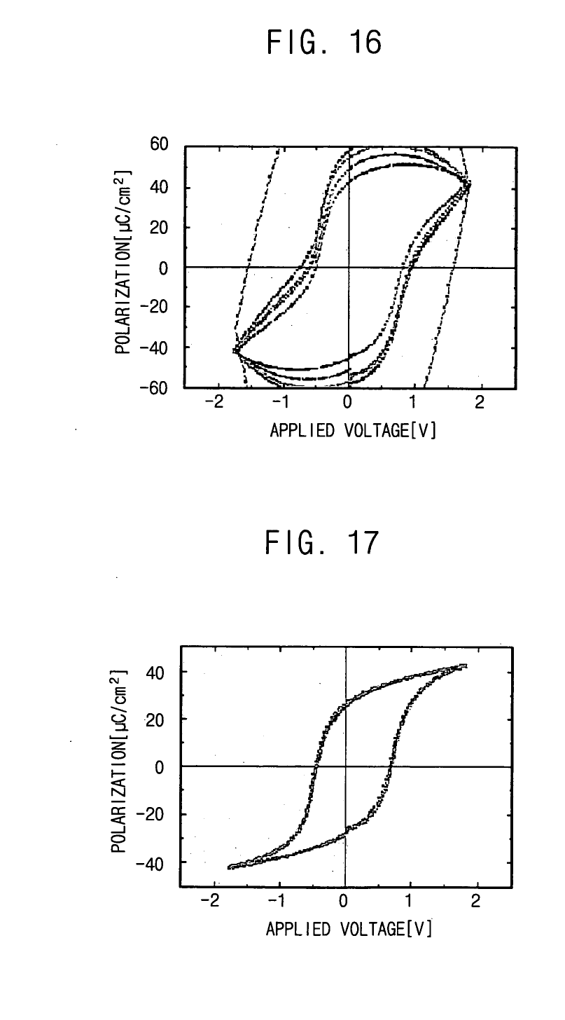

Referring to FIGS. 17 to 19, the ferroelectric capacitor of Example 4 had 2 Pr of about 52.098 μC/cm² and −2 Pr of about −51.765 μC/cm² wherein +Vc was about 0.70V and −Vc was about −0.448V. Additionally, the ferroelectric capacitor of Example 5 had 2 Pr of about 52.658 μC/cm² and −2 Pr of about −52.322 μC/cm² wherein +Vc was about 0.684V and −Vc was about −0.45V. Furthermore, the ferroelectric capacitor of Example 6 had 2 Pr of about 51.86 μC/cm² and −2 Pr of about −51.41 μC/cm² wherein +Vc was about 0.682V and −Vc was about −0.436V.

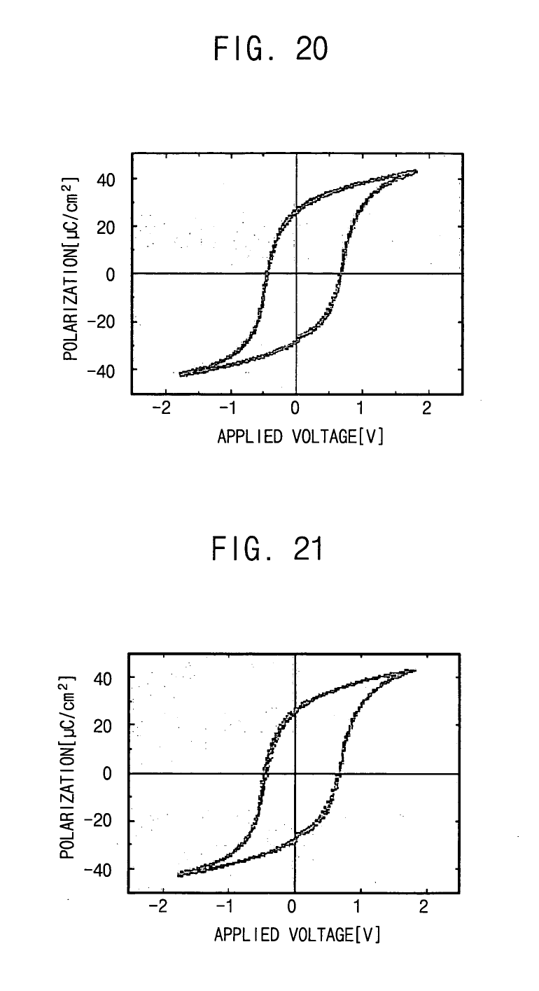

Referring to FIGS. 20 to 22, the ferroelectric capacitor of Example 7 had 2 Pr of about 52.13 μC/cm² and −2 Pr of about −51.81 μC/cm² wherein +Vc was about 0.684V and −Vc was about −0.442V. In addition, the ferroelectric capacitor of Example 8 had 2 Pr of about 51.602 μC/cm² and −2 Pr of about −51.394 μC/cm² wherein +Vc was about 0.68V and −Vc was about −0.442V. Furthermore, the ferroelectric capacitor of Example 9 had 2 Pr of about 52.306 μC/cm² and −2 Pr of about −52.29 μC/cm² wherein +Vc was about 0.694V and −Vc was about −0.458V.

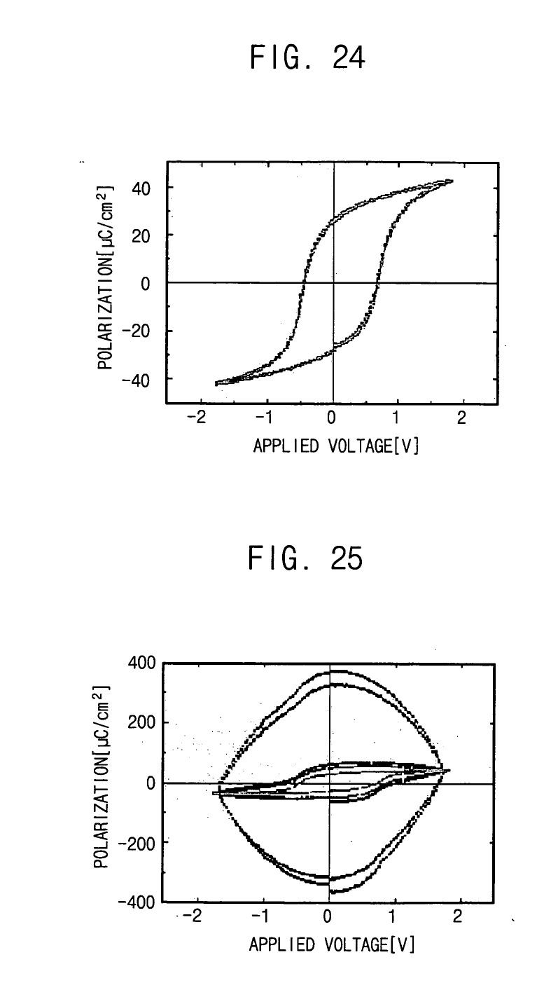

As shown in FIG. 24, the ferroelectric capacitor of Example 11 had 2 Pr of about 51.922 μC/cm² and −2 Pr of about −51.66 μC/cm². Here, +Vc was about 0.686V and −Vc was about −0.446V.

However, the ferroelectric capacitors of Examples 10 and 12 did not show normal P-V hysteresis loops as shown in FIGS. 23 and 25. Hence, it was identified that electrical characteristics of the ferroelectric capacitors of Examples 10 and 12 were deteriorated.

Meanwhile, as shown in FIG. 26, the ferroelectric capacitor of Comparative Example 1 had 2 Pr of about 41.836 C/cm² and −2 Pr of about −41.81 μC/cm² wherein +Vc was about 0.73V and −Vc was about −0.326V.

Therefore, the ferroelectric capacitors of the present invention had electrical characteristics substantially higher than those of the ferroelectric capacitor of Comparative Example 1 except for those of Examples 3, 10 and 12.

FIG. 27 is a graph showing Q-V (charge-voltage) characteristics of the ferroelectric capacitors of Comparative Example 1 and Examples 1, 2, 4 to 9 and 11.

Referring to FIG. 27, all of the ferroelectric capacitors of Examples 1, 2, 4 to 9 and 11 had high Pr of above about 50 μC/cm², whereas the ferroelectric capacitors of Comparative Example 1 has low Pr of below about 40 μC/cm². Therefore, the ferroelectric capacitors of Examples 1, 2, 4 to 9 and 11 had ferroelectric characteristics superior to those of the ferroelectric capacitor of Comparative Example 1.

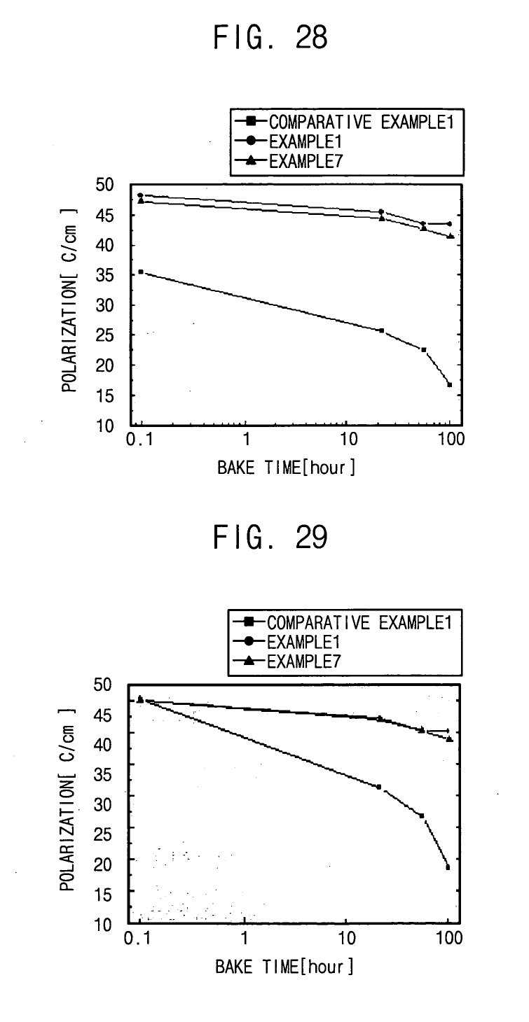

FIGS. 28 and 29 are graphs showing retention characteristics of the ferroelectric capacitors of Comparative Example 1 and Examples 1 and 7. In particular, FIG. 28 shows the polarization retentions of the ferroelectric capacitors relative to time in accordance with Comparative Example 1 and Examples 1 and 7, and FIG. 29 shows the reduction rates of 2 Pr of the ferroelectric capacitors relative to time in accordance with Comparative Example 1 and Examples 1 and 7.

Referring to FIG. 28, after about 100 hours, the ferroelectric capacitor of Example 1 had Pr of about 43.48 μC/cm² at a temperature of about 150° C. In addition, the ferroelectric capacitor of Example 7 had Pr of about 41.49 μC/cm² at a temperature of about 150° C. after about 100 hours. Therefore, the ferroelectric characteristics of the ferroelectric capacitors of Examples 1 and 7 were not deteriorated substantially as time passes. However, after about 100 hours, the ferroelectric capacitor of Comparative Example 1 had Pr of about 16.63 μC/cm² at a temperature of about 150° C. Hence, the ferroelectric characteristics of the ferroelectric capacitors of Comparative Example 1 were deteriorated over time.

As shown in FIG. 29, the ferroelectric capacitor of Example 1 had 2 Pr of about 90.2% of initial 2 Pr thereof at a temperature of about 150° C. after about 100 hours. Additionally, the ferroelectric capacitor of Example 7 had 2 Pr of about 87.6% of initial 2 Pr thereof at a temperature of about 150° C. after about 100 hours. Thus, the ferroelectric characteristics of the ferroelectric capacitors of Examples 1 and 7 were not substantially reduced over time. However, the ferroelectric capacitor of Comparative Example 1 had 2 Pr of about 47.0% of initial 2 Pr thereof at a temperature of about 150° C. after about 100 hours. Therefore, the ferroelectric characteristics of the ferroelectric capacitors of Comparative Example 1 were reduced over time.

### EXAMPLE 13

A first upper electrode layer pattern was formed on a ferroelectric layer pattern using strontium ruthenium oxide doped with copper by a concentration of about 4 atomic weight percent based on an entire atomic weight of strontium ruthenium oxide. A second upper electrode layer pattern was formed on the first upper electrode layer pattern using iridium. Each of the first and the second upper electrode layer patterns was formed by applying a power of about 600 W and providing an argon gas with a flow rate of about 40 sccm. The first upper electrode layer pattern had a thickness of about 50 Å, and the second upper electrode layer pattern had a thickness of about 600 Å.

After forming the first and second upper electrode layer patterns on the ferroelectric layer pattern, these patterns were treated by a rapid thermal process at a temperature of about 600° C. for about 1 minute under an oxygen atmosphere.

### EXAMPLE 14

A first upper electrode layer pattern was formed on a ferroelectric layer pattern using strontium ruthenium oxide doped with copper by a concentration of about 4 atomic weight percent based on an entire atomic weight of strontium ruthenium oxide. The first upper electrode layer pattern was formed by applying a power of about 600 W and providing an argon gas with a flow rate of about 40 sccm. The first upper electrode layer pattern had a thickness of about 50 Å.

Then, the first upper electrode layer pattern and the ferroelectric layer pattern were thermally treated by a rapid thermal process at a temperature of about 650° C. for about 1 minute under an oxygen atmosphere.

A second upper electrode layer pattern was formed on the thermally treated first upper electrode layer pattern using iridium. The second upper electrode layer pattern was formed by applying a power of about 600 W and providing an argon gas with a flow rate of about 40 sccm. The second upper electrode layer pattern had a thickness of about 600 Å.

### EXAMPLE 15

A first upper electrode layer pattern was formed on a ferroelectric layer pattern using strontium ruthenium oxide doped with copper by a concentration of about 4 atomic weight percent based on an entire atomic weight of strontium ruthenium oxide. A second upper electrode layer pattern was formed on the first upper electrode layer pattern using iridium. Each of the first and the second upper electrode layer patterns was formed by applying a power of about 600 W and providing an argon gas with a flow rate of about 40 sccm. The first upper electrode layer pattern had a thickness of about 50 Å, and the second upper electrode layer pattern had a thickness of about 600 Å.

After forming the first and second upper electrode layer patterns on the ferroelectric layer pattern, these patterns were treated by a rapid thermal process at a temperature of about 600° C. for about 1 minute under a nitrogen atmosphere.

### EXAMPLE 16

A first upper electrode layer pattern was formed on a ferroelectric layer pattern using strontium ruthenium oxide doped with copper by a concentration of about 4 atomic weight percent based on an entire atomic weight of strontium ruthenium oxide. A second upper electrode layer pattern was formed on the first upper electrode layer pattern using iridium. Each of the first and the second upper electrode layer patterns was formed by applying a power of about 600 W and providing an argon gas with a flow rate of about 40 sccm. The first upper electrode layer pattern had a thickness of about 50 Å, and the second upper electrode layer pattern had a thickness of about 600 Å.

After forming the first and second upper electrode layer patterns on the ferroelectric layer pattern, these patterns were treated by a rapid thermal process at a temperature of about 600° C. for about 3 minute under an oxygen atmosphere.

### EXAMPLE 17

A first upper electrode layer pattern was formed on a ferroelectric layer pattern using strontium ruthenium oxide doped with copper by a concentration of about 4 atomic weight percent based on an entire atomic weight of strontium ruthenium oxide. A second upper electrode layer pattern was formed on the first upper electrode layer pattern using iridium. Each of the first and the second upper electrode layer patterns was formed by applying a power of about 600 W and providing an argon gas with a flow rate of about 40 sccm. The first upper electrode layer pattern had a thickness of about 50 Å, and the second upper electrode layer pattern had a thickness of about 600 Å.

After forming the first and second upper electrode layer patterns on the ferroelectric layer pattern, these patterns were treated by a rapid thermal process at a temperature of about 650° C. for about 1 minute under a nitrogen atmosphere.

### COMPARATIVE EXAMPLE 2

A first upper electrode layer pattern was formed on a ferroelectric layer pattern using strontium ruthenium oxide doped with copper by a concentration of about 4 atomic weight percent based on an entire atomic weight of strontium ruthenium oxide. After a second upper electrode layer pattern was formed on the first upper electrode layer pattern using iridium oxide, a third upper electrode layer pattern including iridium was formed on the second upper electrode layer pattern. Each of the first to the third upper electrode layer patterns was formed by applying a power of about 600 W and providing an argon gas with a flow rate of about 40 sccm. The first upper electrode layer pattern had a thickness of about 50 Å, the second upper electrode layer pattern had a thickness of about 300 Å, and the third upper electrode layer pattern had a thickness of about 400 Å.

After forming the first to the third upper electrode layer patterns on the ferroelectric layer pattern, these patterns were thermally treated by a rapid thermal process at a temperature of about 600° C. for about 1 minute under an oxygen atmosphere.

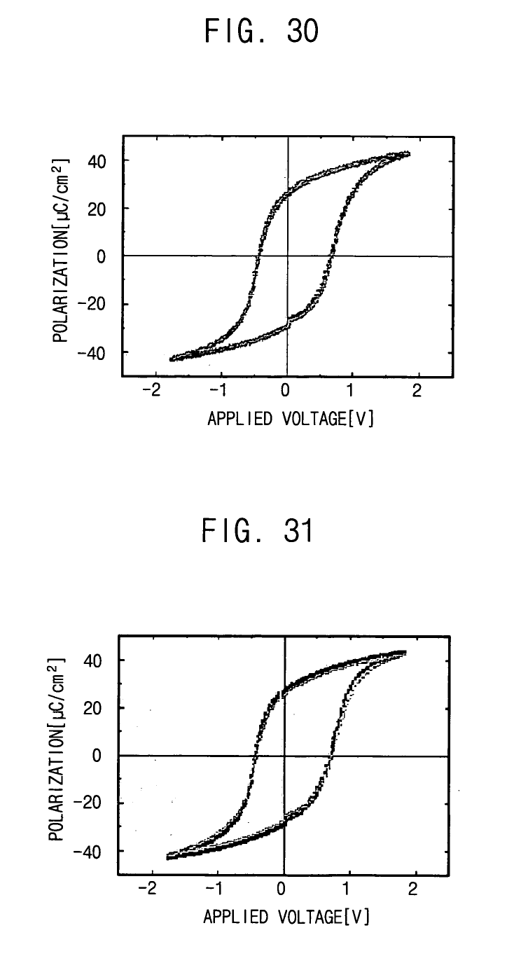

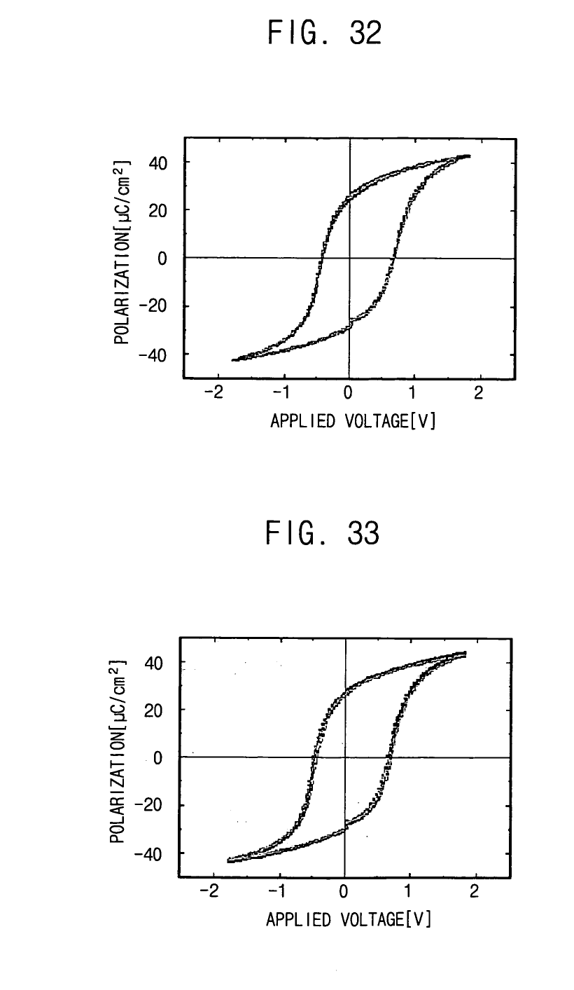

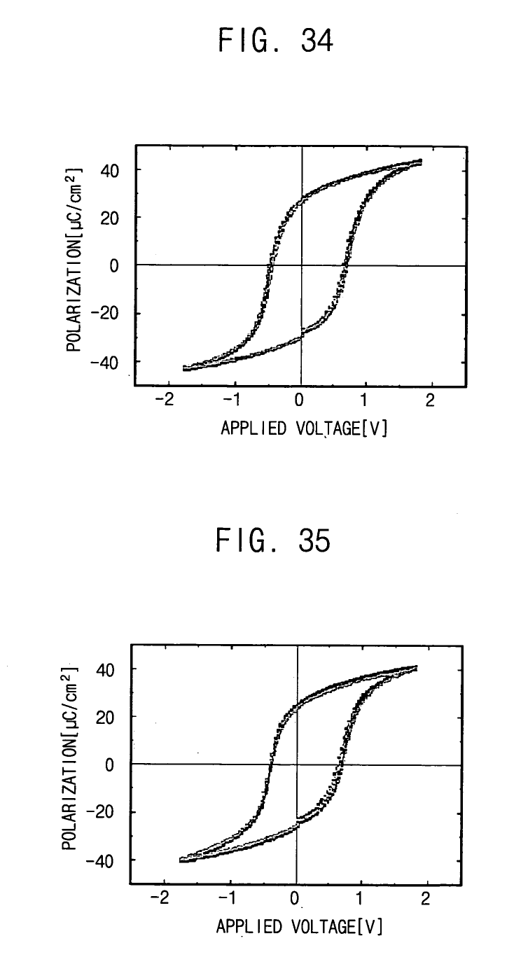

FIGS. 30 to 34 are graphs showing P-V hysteresis loops of ferroelectric capacitors in accordance with Examples 13 to 17. FIG. 35 is a graph showing a P-V hysteresis loop of a ferroelectric capacitor in accordance with Comparative Example 2. In FIGS. 30 to 35, the P-V hysteresis loops of ferroelectric capacitors were obtained by measuring polarizations relative to applied voltages.

Referring to FIGS. 30 to 34, the ferroelectric capacitors of Examples 13 to 17 had minimum 2 Pr of above about 50 μC/cm² and minimum −2 Pr of below about −50 μC/cm². In particular, the ferroelectric capacitor of Example 16 had the maximum 2 Pr of about 53.7 μC/cm². However, as shown in FIG. 35, the ferroelectric capacitor of Comparative Example 2 had maximum 2 Pr of below about 45 μC/cm² and maximum −2 Pr of above about −45 μC/cm². Therefore, the ferroelectric capacitors of Examples 13 to 17 had electrical characteristics superior to those of the ferroelectric capacitor of Comparative Example 2.

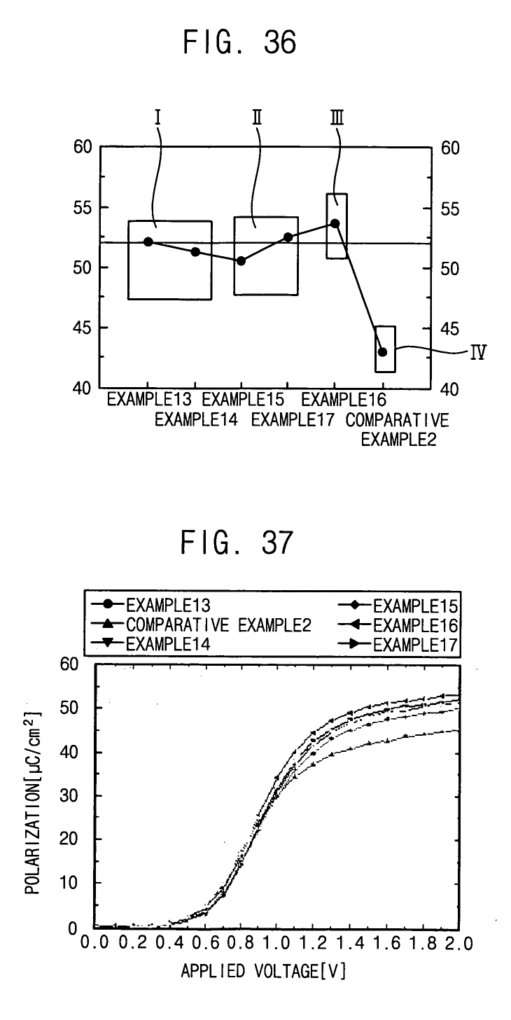

FIG. 36 is a graph showing retention characteristics of the ferroelectric capacitors of Comparative Example 2 and Examples 13 and 17. In FIG. 36, “I” indicates 2 Pr of the ferroelectric capacitors of Examples 13 and 14 in which the ferroelectric capacitors were thermally treated under the oxygen atmosphere for about 1 minute. “II” represents 2 Pr of the ferroelectric capacitors of Examples 15 and 17 wherein the ferroelectric capacitors were thermally treated under the nitrogen atmosphere for about 1 minute. “III” indicates 2 Pr of the ferroelectric capacitor of Example 16 wherein the ferroelectric capacitors was thermally treated under the oxygen atmosphere for about 3 minute. “IV” represents 2 Pr of the ferroelectric capacitors of Comparative Example 2 in which the ferroelectric capacitor was thermally treated under the oxygen atmosphere for about 1 minute.

As shown in FIG. 36, all of the ferroelectric capacitors of Examples 13 to 17 had relatively high minimum 2 Pr of above about 50 μC/cm², whereas the ferroelectric capacitor of Comparative Example 2 has relatively low maximum 2 Pr of about 43 μC/cm².

FIG. 37 is a graph showing Q-V characteristics of the ferroelectric capacitors of Comparative Example 2 and Examples 13 and 17. Referring to FIG. 37, the ferroelectric capacitors of Examples 13 to 17 had relatively high minimum Pr of above about 50 μC/cm², whereas the ferroelectric capacitor of Comparative Example 2 has relatively low maximum Pr of about 45 μC/cm².

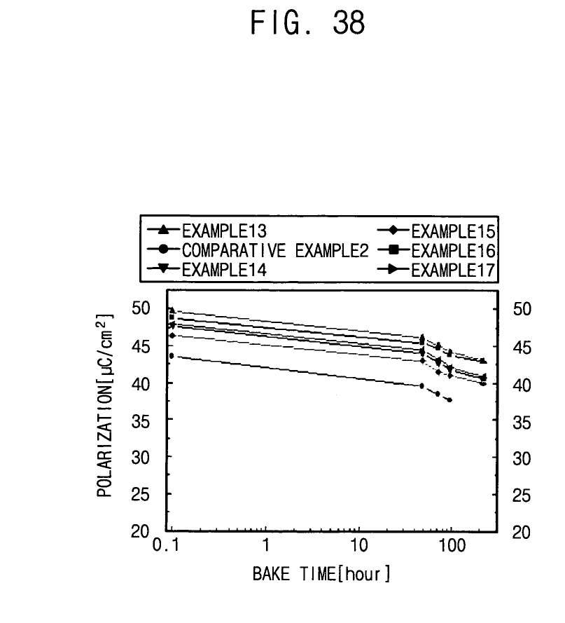

FIG. 38 is a graph showing retention characteristics of the ferroelectric capacitors of Comparative Example 2 and Examples 13 and 17. Particularly, FIG. 38 shows the polarization retentions of the ferroelectric capacitors relative to time in accordance with Comparative Example 1 and Examples 13 and 17.

Referring to FIG. 38, the ferroelectric capacitors of Examples 13 to 17 had Pr of above about 40 μC/cm² at a temperature of about 150° C. after about 100 hours. Therefore, the ferroelectric characteristics of the ferroelectric capacitors of Examples 13 to 17 were not deteriorated substantially over time. However, the ferroelectric capacitor of Comparative Example 2 had Pr of about 33 μC/cm² at a temperature of about 150° C. after about 100 hours. Thus, the ferroelectric characteristics of the ferroelectric capacitors of Comparative Example 2 were greatly deteriorated as time passes.

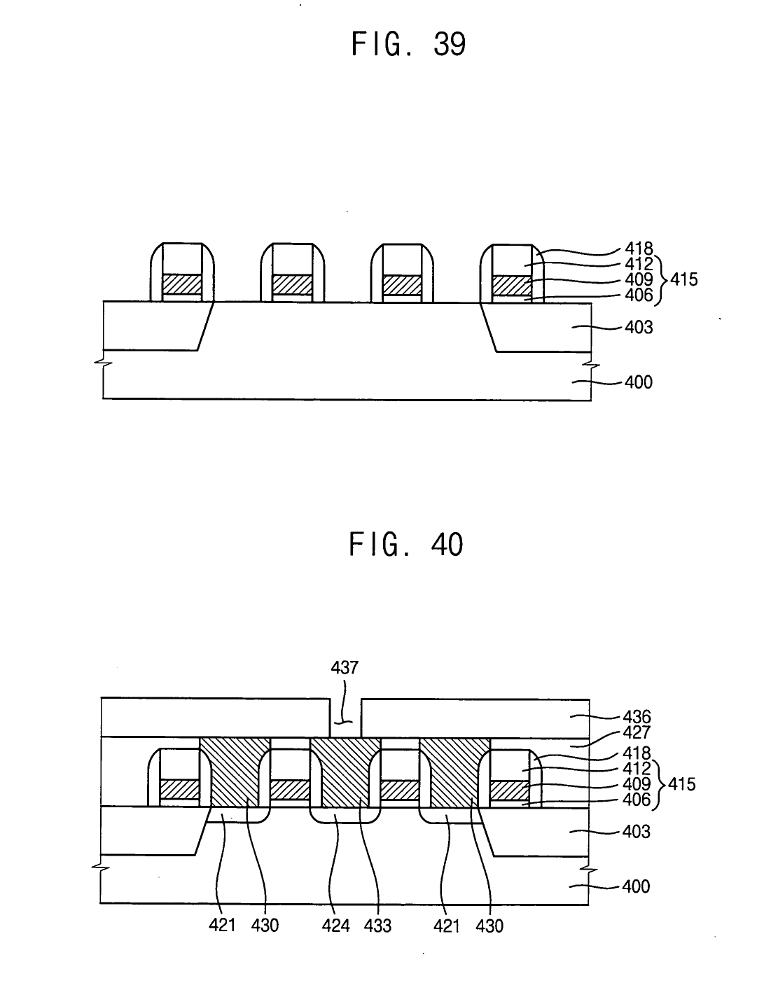

FIGS. 39 to 45 are cross-sectional views illustrating a semiconductor device including a ferroelectric structure in accordance with some exemplary embodiments of the present invention. Referring to FIG. 39, an isolation layer 403 is formed on a semiconductor substrate 400 so that an active region and a field region are defined on the substrate 400. The isolation layer 403 may be formed an isolation process such as a shallow trench isolation (STI) process or a local oxidation of silicon (LOCOS) process.

A thin gate oxide layer is formed on the active region of the substrate 400. The thin gate oxide layer may be formed on the substrate 400 by a thermal oxidation process or a CVD process.

A first conductive layer and a first mask layer are sequentially formed on the thin gate oxide layer. The first conductive layer and the first mask layer may correspond to a gate conductive layer and a gate mask layer, respectively. The first conductive layer will be patterned to form a gate conductive pattern 409. The first conductive layer may include doped polysilicon. Alternatively, the first conductive layer may have a polycide structure that includes doped polysilicon and metal silicide. The first mask layer will be patterned to form a gate mask pattern 412. The first mask layer may include a material that has an etching selectivity relative to a first insulating interlayer 427 (see FIG. 40). For example, the first mask layer includes a nitride such as silicon nitride when the first insulating interlayer 427 includes an oxide.

After a first photoresist pattern (not shown) is formed on the first mask layer, the first mask layer, the first conductive layer and the thin gate oxide layer are etched using the first photoresist pattern as an etching mask. As a result, gate structures 415 are formed on the substrate 400. Each of the gate structures 415 includes a gate oxide layer pattern 406, the gate conductive pattern 409 and the gate mask pattern 412.

In some embodiments of the present invention, after the first photoresist pattern is formed on the first mask layer, the first mask layer is etched to thereby form the gate mask pattern 412 on the first conductive layer. After removing the first photoresist pattern by an ashing process and/or a stripping process, the first conductive layer and the thin gate oxide layer are sequentially etched using the gate mask pattern 412 as an etching mask to thereby form the gate conductive pattern 409 and the gate oxide layer pattern 406.

After a first insulation layer is formed on the substrate 400 to cover the gate structures 415, the first insulation layer is anisotropically etched to form gate spacers 418 on sidewalls of the gate structures 415. The first insulation layer may include a nitride such as silicon nitride.

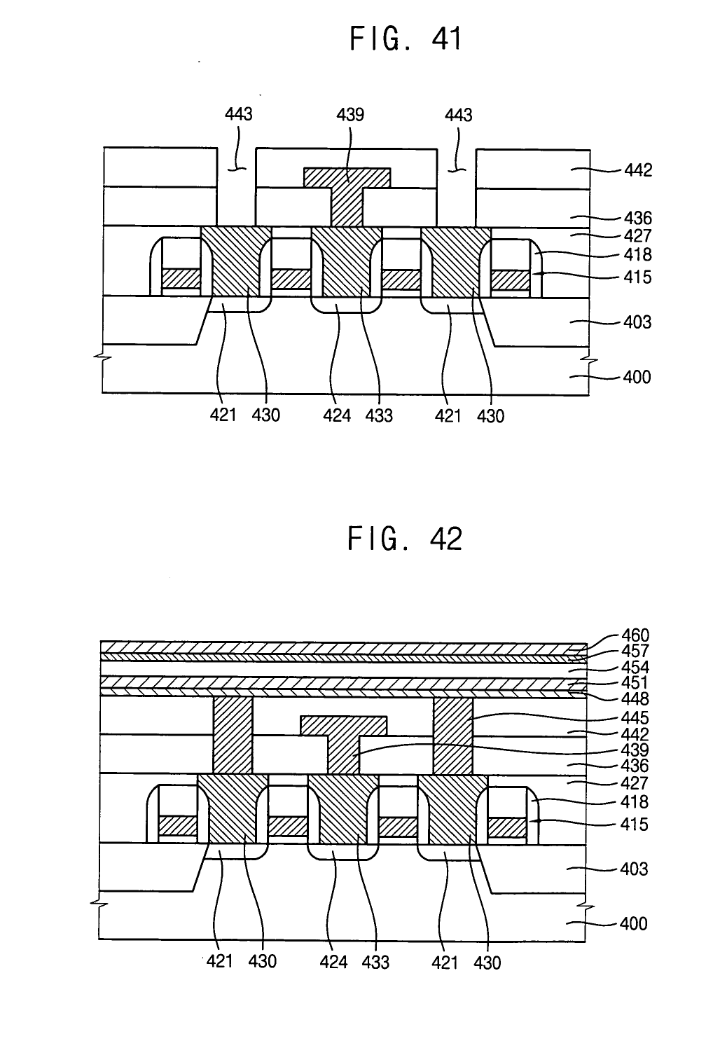

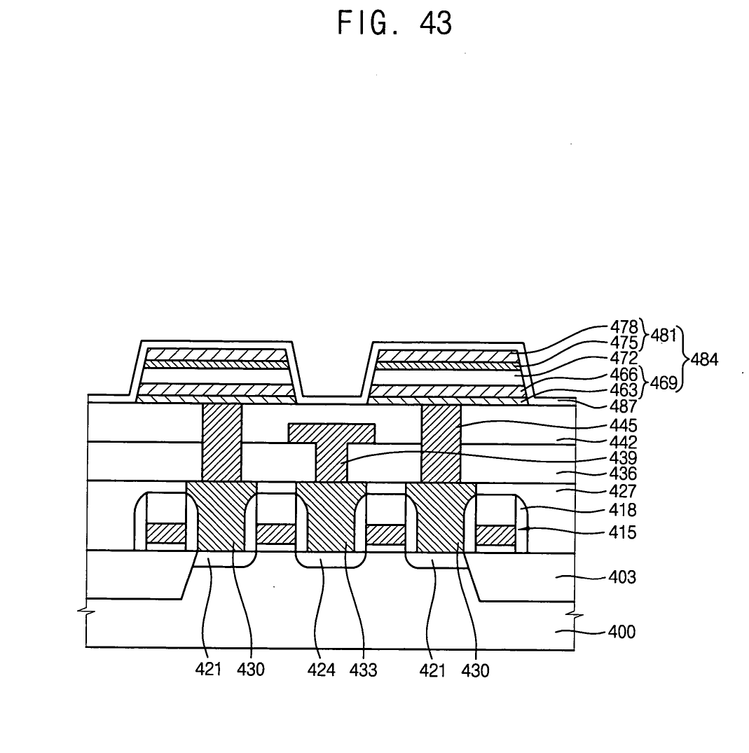

Referring to FIG. 40, impurities are implanted into portions of the substrate 400 exposed by the gate structures 415 using the gate structures 415 and the gate spacers 418 as ion implantation masks. Hence, a first contact region 421 and a second contact region 424 are formed at the exposed portions of the substrate 400. The first and the second contact regions 421 and 424 may correspond to source/drain regions, respectively. The first and the second contact regions 421 and 424 are divided into a capacitor contact region and a bit line contact region. A ferroelectric capacitor 484 (see FIG. 43) is electrically connected to the capacitor contact region, and a bit line 439 (see FIG. 41) is electrically connected to the bit line contact region. For example, the first contact region 421 corresponds to the capacitor contact region, and the second contact region 424 corresponds to the bit line contact region. When the first and the second contact regions 421 and 424 are formed, transistors including the gate structures 415 and the contact regions 421 and 424 are completed on the substrate 400.

In some embodiments of the present invention, first impurities are implanted into the portions of the substrate 400 exposed by the gate structures 415 with a relative low concentration before forming the gate spacers 418. After forming the gate spacers 418, second impurities are implanted into the portions of the substrate 400 with a relatively high concentration. As a result, the first and the second contact regions 421 and 424 may have lightly doped drain (LDD) structures, respectively.

Referring now FIG. 40, the first insulating interlayer 427 is formed on the substrate 400 to cover the transistors including the gate structures 415. The first insulating interlayer 427 may include an oxide such as boro-phosphor silicate glass (BPSG), phosphor silicate glass (PSG), spin on glass (SOG), plasma enhanced-tetra ethyl ortho silicate (PE-TEOS), undoped silicate glass (USG), high density plasma-chemical vapor deposition (HDP-CVD) oxide, etc. The first insulating interlayer 427 may be formed on the substrate 400 by a CVD process, PECVD process, an HDP-CVD process or an ALD process.

An upper portion of the first insulating interlayer 427 is removed by a CMP process, an etch back process or a combination process of CMP and etch back, thereby planarizing the first insulating interlayer 427. Here, the first insulating interlayer 427 has an upper face slightly higher than that of the gate mask pattern 418. Alternatively, the first insulating interlayer 427 may be planarized until the gate mask pattern 418 is exposed so that the first insulating interlayer 427 has an upper face substantially equal to that of the gate mask pattern 412.

After a second photoresist pattern (not shown) is formed on the insulating interlayer 427, portions of the first insulating interlayer 427 are anisotropically etched to form first contact holes that expose the first and the second contact regions 421 and 424, respectively. When the first insulating interlayer 427 includes the oxide, the first insulating interlayer 427 may be partially etched using an etching gas that has an etching selectivity of the first insulating interlayer 427 relative to the gate mask pattern 412 and the gate spacer 418. Therefore, the first contact holes are self-aligned relative to the gate spacer 418 and the gate mask pattern 412. Some first contact holes may expose the first contact regions 412, and other first contact hole may expose the second contact region 424.

After removing the second photoresist pattern by an ashing process and/or a stripping process, a second conductive layer is formed on the first insulating interlayer 427 to fill up the first contact holes. The second conductive layer may include doped polysilicon or a metal such as tungsten, aluminum, titanium, copper, etc.

The second conductive layer are partially removed by a CMP process, an etch back process or a combination process of CMP and etch back until the first insulating interlayer 427 is exposed. Thus, a first pad 430 and a second pad 433 are formed in the first contact holes. Since the first contact holes are formed through the self-alignment process, the first and the second pads 430 and 433 also correspond to self-aligned contact (SAC) pads, respectively. The first pad 430 contacts the first contact region 421, and the second pad 433 makes contact with the second contact region 424. For example, the first pad 430 is positioned on the capacitor contact region, and the second pad 433 is formed on the bit line contact region.

In some embodiments of the present invention, the second conductive layer is partially removed until the gate mask pattern 412 is exposed to thereby from the first and the second pads 430 and 433 when the first insulation interlayer 427 is planarized until the gate mask pattern 412 is exposed. Hence, each of the first and the second pads 430 and 433 may have a height substantially identical to that of the gate mask pattern 412.

A second insulating interlayer 436 is formed on the insulating interlayer 427, the first pad 430 and the second pad 433. The second insulating interlayer 436 insulates the first pads 430 from the bit line 439. The second insulating interlayer 436 may include an oxide such as BPSG, PSG, SOG, PE-TEOS, USG, HDP-CVD oxide, etc. The second insulating interlayer 436 may be formed by a CVD process, a PECVD process, an HDP-CVD process or an ALD process. In some embodiments of the present invention, the second insulating interlayer 436 may include the oxide substantially identical to that of the first insulating interlayer 427. In another embodiment of the present invention, the second insulating interlayer 436 may include the oxide different from that of the first insulating interlayer 427.

To maintain a process margin of a successive photolithography process, an upper portion of the second insulating interlayer 436 is planarized by a CMP process, an etch back process or a combination process of CMP and etch back.

After a third photoresist pattern (not shown) is formed on the planarized second insulating interlayer 436, the second insulating interlayer 436 is partially etched using the third photoresist pattern as an etching mask. Thus, a second contact hole 437 is formed through the second insulating interlayer 436. The second contact hole 437 exposes the second pad 433 buried in the first insulating interlayer 427.

In some embodiments of the present invention, a first anti-reflective layer (ARL) may be formed between the second insulating interlayer 436 and the third photoresist pattern so as to sufficiently ensure the process margin of the photolithography process. The first ARL may include silicon oxide, silicon nitride or silicon oxynitride.

Referring to FIG. 41, after the third photoresist pattern is removed by an ashing process and/or a stripping process, a third conductive layer is formed on the second insulating interlayer 436 to fill up the second contact hole 437. The third conductive layer may include doped polysilicon or a metal such as tungsten, aluminum, titanium, copper, etc.

After a fourth photoresist pattern is formed on the third conductive layer, the third conductive layer is etched using the fourth photoresist pattern as an etching mask, thereby forming the bit line 439 filling the second contact hole 437 on the second insulating interlayer 436. In some embodiments of the present invention, the bit line 439 may include a first film of metal/metal nitride and a second film of metal. For example, the first film includes titanium/titanium nitride, and the second film includes tungsten.

A third insulating interlayer 442 is formed on the second insulating interlayer 436 to cover the bit line 439. The third insulating interlayer 442 may be formed using a CVD process, a PECVD process, an HDP-CVD process or an ALD process. The third insulating interlayer 442 may include an oxide such as BPSG, PSG, SOG, PE-TEOS, USG, HDP-CVD oxide, etc. As described above, the third insulating interlayer 442 may include the oxide substantially identical to that of the first insulating interlayer 427 and/or the second insulating interlayer 436. Alternatively, the third insulating interlayer 442 may include the oxide different from that of the first insulating interlayer 427 and/or the second insulating interlayer 436. For example, the third insulating interlayer 442 is formed using HDP-CVD oxide because HDP-CVD oxide may be deposited at a relatively low temperature and also a gap or a hole may be completely filled with HDP-CVD oxide without a void therein.

In some embodiments of the present invention, an additional insulation layer of nitride may be formed on the bit line 439 and the second insulating interlayer 436 in order to reduce the likelihood of forming a void from at a portion of the third insulating interlayer 442 between adjacent bit lines 439. Then, the third insulating interlayer 442 may be formed on the additional insulation layer.

The third insulating interlayer 442 is planarized by a CMP process, an etch back process or a combination process of CMP and etch back.

After a fifth photoresist pattern (not shown) is formed on the planarized third insulating interlayer 442, the third insulating interlayer 442 and the second insulating interlayer 436 are partially etched using the fifth photoresist pattern as an etching mask. Hence, third contact holes 443 are formed through the third insulating interlayer 442 and the second insulating interlayer 436 to expose the first pads 430.

In some embodiments according to the present invention, a second ARL may be formed between the third insulating interlayer 442 and the fifth photoresist pattern so as to ensure a process margin of the etching process. In some embodiments according to the present invention, a cleaning process may be performed to remove a native oxide film or particles from the first pads 430 after the third contact holes 443 are formed.

Referring to FIG. 42, a fourth conductive layer is formed on the third insulating interlayer 442 to fill up the third contact holes 443, and then the fourth conductive layer is partially removed by a CMP process, an etch back process or a combination process of CMP and etch back until the third insulating interlayer 442 is exposed. As a result, third pads 445 are formed in the third contact holes 443, respectively. Each of the third pads 445 may include doped polysilicon or a metal such as tungsten, aluminum, copper, titanium, etc. The third pad 445 electrically connects the first pad 430 to a lower electrode 469 of the ferroelectric capacitor 484 (see FIG. 43). That is, the lower electrode 469 of the ferroelectric capacitor 484 electrically contacts to the first contact region 421 through the third pad 445 and the first pad 430.

A first lower electrode layer 448 and a second lower electrode layer 451 are sequentially formed on the third pads 445 and the third insulating interlayer 442. The first lower electrode layer 448 may have a thickness of about 50 to about 300 Å, and the second lower electrode layer 451 may have a thickness of about 300 to about 1,000 Å. The first lower electrode layer 448 may be formed using a metal nitride by a CVD process, a sputtering process or an ALD process. The second lower electrode layer 451 may be formed using a first metal by a sputtering process, a PLD process or an ALD process. The second lower electrode layer 451 may be formed on the first lower electrode layer 448 at a temperature of about 20 to about 350° C. and a pressure of about 3 to about 10 mTorr while applying a power of about 300 to about 1,000 W under an inactive gas atmosphere.

A ferroelectric layer 454 is formed on the second lower electrode layer 451 to have a thickness of about 200 to about 1,000 Å. The ferroelectric layer 454 may be formed by a metal organic chemical vapor deposition process, a sol-gel process or an ALD process. The ferroelectric layer 454 may include a metal oxide or a ferroelectric material doped with copper, lead or bismuth.

In some embodiments of the present invention, a third lower electrode layer (not shown) may be formed between the second lower electrode layer 451 and the ferroelectric layer 454. The third lower electrode layer may have a thickness of about 10 to about 500 Å. The third lower electrode layer may include a second metal oxide doped with a fourth metal as described above. For example, the third lower electrode layer includes SRO, STO, LNO or CRO doped with copper, lead or bismuth. The third lower electrode layer may be formed on the second lower electrode layer 451 at a temperature of about 20 to about 600° C. and a pressure of about 3 to about 10 mTorr while applying a power of about 300 to about 1,000 W under an inactive gas atmosphere.

A first upper electrode layer 457 is formed on the ferroelectric layer 454 to have a thickness of about 10 to about 300 Å. The first upper electrode layer 457 may include a first metal oxide doped with a second metal as described above. The first upper electrode layer 457 may be formed at a temperature of about 20 to about 350° C. and a pressure of about 3 to about 10 mTorr while applying a power of about 300 to about 1,000 W under an inactive gas atmosphere.

A second upper electrode layer 460 is formed on the first upper electrode layer 457 to have a thickness of about 300 to about 1,000 Å. The second upper electrode layer 460 may include a third as described above. The second upper electrode layer 460 may be formed at a temperature of about 20 to about 350° C. and a pressure of about 3 to about 10 mTorr while applying a power of about 300 to about 1,000 W under an inactive gas atmosphere.

After forming the second upper electrode layer 460, the substrate 400 having the ferroelectric layer 454 and the first upper electrode layer 457 is thermally treated under an oxygen atmosphere, a nitrogen atmosphere or a mixture atmosphere including oxygen or nitrogen. The ferroelectric layer 454 and the first upper electrode layer 457 may be treated by a RTP at a temperature of about 500 to about 650° C.

Referring to FIG. 43, a sixth photoresist pattern (not shown) is formed on the second upper electrode layer 460. Using the sixth photoresist pattern as an etching mask, the second upper electrode layer 460, the first upper electrode layer 457, the ferroelectric layer 454, the second lower electrode layer 451 and the first lower electrode layer 448 are sequentially etched. As a result, the ferroelectric capacitor 484 including the lower electrode 469, a ferroelectric layer pattern 472 and an upper electrode 481 is formed over the substrate 400. The lower electrode layer 469 includes a first lower electrode layer pattern 463 and a second lower electrode layer pattern 466 successively formed on the third pads 445 and the third insulating interlayer 442. The upper electrode 481 includes a first upper electrode layer pattern 475 and a second upper electrode layer pattern 478 sequentially formed on the ferroelectric layer pattern 472. The ferroelectric capacitor 484 may have a sidewall inclined by an angle of about 50 to about 80° relative to a horizontal direction.

A barrier layer 487 is formed on the third insulating interlayer 442 to cover the ferroelectric capacitor 484. The barrier layer 487 may include a metal oxide or a metal nitride. For example, the barrier layer 487 includes aluminum oxide, titanium nitride or silicon nitride. The barrier layer 487 may be formed by a CVD process, a sputtering process or an ALD process. The barrier layer 487 may reduce the amount of hydrogen atoms from diffusing into the ferroelectric layer pattern 472 so that the barrier layer 487 may improve electrical characteristics of the ferroelectric layer pattern 472. However, the barrier layer 487 may be omitted as occasion demands.

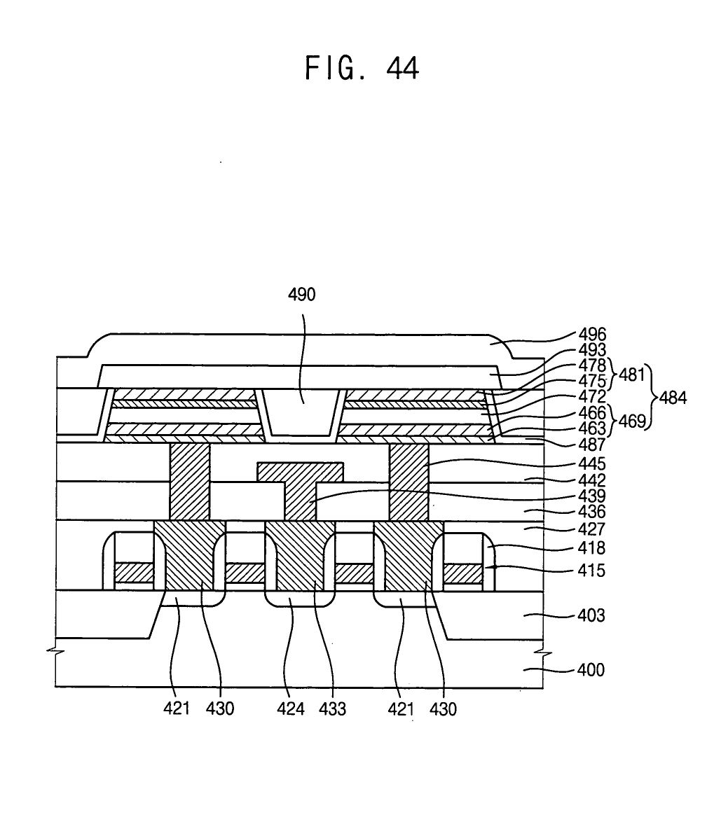

Referring to FIG. 44, a fourth insulating interlayer 490 is formed on the barrier layer 487. The fourth insulating interlayer 490 may include an oxide such as BPSG, PSG, SOG, PE-TEOS, USG, HDP-CVD oxide, etc. The fourth insulating interlayer 490 may be formed by a CVD process, a PECVD process, an HDP-CVD process or an ALD process.

The fourth insulating interlayer 490 and the barrier layer 487 are partially removed by a CMP process, an etch back process or a combination process of CMP and etch back until the upper electrode 481 is exposed.

A fifth conductive layer is formed on the exposed upper electrode 481 and the fourth insulating interlayer 490 by a CVD process, a sputtering process or an ALD process. The fifth conductive layer may include a metal, a conductive metal oxide or a conductive metal nitride. For example, the fifth conductive layer includes titanium aluminum nitride, aluminum, titanium, titanium nitride, iridium, iridium oxide, platinum, ruthenium, ruthenium oxide, etc.

After a seventh photoresist pattern (not shown) is formed on the fifth conductive layer, the fifth conductive layer is etched using the seventh photoresist pattern as an etching mask, thereby forming a local plate line 493 contacting the upper electrode 481. The local plate line 493 makes commonly contact with adjacent upper electrodes 481 of adjacent ferroelectric capacitors 484.

A fifth insulating interlayer 496 is formed on the local plate line 493 and the fourth insulating interlayer 490. The fifth insulating interlayer 496 may include an oxide such as BPSG, PSG, SOG, PE-TEOS, USG, HDP-CVD oxide, etc. The fifth insulating interlayer 496 may be formed by a CVD process, a PECVD process, an HDP-CVD process or an ALD process.

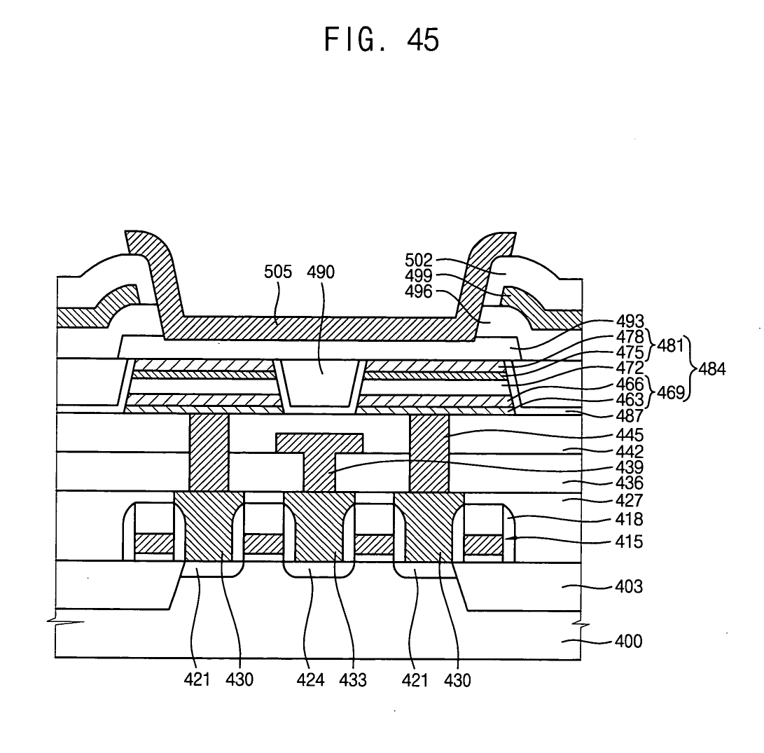

Referring to FIG. 45, a sixth conductive layer is formed on the fifth insulating interlayer 496 using a metal or a conductive metal nitride. For example, the sixth conductive layer includes aluminum, titanium, titanium nitride, titanium aluminum nitride, etc. The sixth conductive layer may be formed by a sputtering process, an ALD process, a PLD process or a CVD process.

After an eighth photoresist pattern (not shown) is formed on the sixth conductive layer, the sixth conductive layer is etched using the eighth photoresist pattern as an etching mask, thereby forming a first upper wiring 499 on the fifth insulating interlayer 496.

A sixth insulating interlayer 502 is formed on the first upper wiring 499 and the fifth insulating interlayer 496, and then a ninth photoresist pattern (not shown) is formed on the sixth insulating interlayer 502. The sixth insulating interlayer 502 may include an oxide such as BPSG, PSG, SOG, PE-TEOS, USG, HDP-CVD oxide, etc. The sixth insulating interlayer 502 may be formed by a CVD process, a PECVD process, an HDP-CVD process or an ALD process.

Using the ninth photoresist pattern as an etching mask, the sixth insulating interlayer 502 and the fifth insulating interlayer 496 are partially etched to expose the local plate line 493.

A seventh conductive layer is formed on the exposed local plate line 493. The seventh conductive layer may include a metal or a metal nitride such as aluminum, titanium, titanium nitride, titanium aluminum nitride, etc. The seventh conductive layer may be formed by a sputtering process, a PLD process, an ALD process or a CVD process.

After a tenth photoresist pattern (not shown) is formed on the seventh conductive layer, the seventh conductive layer is etched using the tenth photoresist pattern as an etching mask. Thus, a main plate line 505 contacting the local plate line 493 is formed. As a result, a semiconductor device including the ferroelectric capacitor 484 is completed.

According to the present invention, an upper electrode and/or a lower electrode may include a metal oxide doped with a metal such as copper, lead or bismuth by a concentration of about 2 to about 5 atomic weight percent based on an entire atomic weight of the metal oxide such as SRO, STO, LNO or CRO. Particularly, the ferroelectric layer may be relatively thin and a ferroelectric capacitor including the ferroelectric layer may have enhanced electrical characteristics when the upper electrode and/or the lower electrode may include SRO doped with copper, lead or bismuth. Additionally, when the ferroelectric layer includes PZT formed by a metal organic chemical vapor deposition process, and the upper electrode and/or the lower electrode has a composite structure that includes iridium and SRO, process margins of manufacturing processes for the ferroelectric capacitor, for example, temperature, pressure, gases and atmosphere, may be sufficiently ensured. Furthermore, the semiconductor device including the ferroelectric capacitor may be efficiently operated at a relatively low voltage of below about 1.6V.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A ferroelectric structure comprising:
a lower electrode including a first metal;
a ferroelectric layer formed on the lower electrode; and
an upper electrode formed on the ferroelectric layer, the upper electrode including a first metal oxide doped with a second metal, and a third metal.

2. The ferroelectric structure of claim 1, wherein the ferroelectric layer comprises PZT including zirconium (Zr) and titanium (Ti) by a weight ratio of about 25:75 to about 40:60, which is formed using a metal organic chemical vapor deposition process.

3. The ferroelectric structure of claim 1, wherein each of the first metal and the third metal comprises any one selected from the group consisting of iridium (Ir), platinum (Pt), ruthenium (Ru), palladium (Pd) and gold (Au), the second metal comprises any one selected from the group consisting of copper (Cu), lead (Pb) and bismuth (Bi), and the first metal oxide comprises any one selected from the group consisting of strontium ruthenium oxide (SRO), strontium titanium oxide (STO), lanthanum nickel oxide (LNO) and calcium ruthenium oxide (CRO).

4. The ferroelectric structure of claim 1, wherein the upper electrode comprises the first metal oxide doped with the second metal by a concentration of about to 2 to about 5 atomic weight percent based on an entire atomic weight of the first metal oxide.

5. The ferroelectric structure of claim 1, wherein the upper electrode comprises:
a first upper electrode layer formed on the ferroelectric layer, the first upper electrode layer including the first metal oxide doped with the second metal; and
a second upper electrode layer formed on the first upper electrode layer, the second upper electrode layer including the third metal.

6. The ferroelectric structure of claim 5, wherein the lower electrode comprises:
a first lower electrode layer; and
a second lower electrode layer formed on the first lower electrode layer, the second lower electrode layer including the first metal.

7. The ferroelectric structure of claim 6, wherein the first lower electrode layer comprises any one selected from the group consisting of titanium aluminum nitride (TiAlN), aluminum nitride (AlN), titanium nitride (TiN), titanium silicon nitride (TiSiN), tantalum nitride (TaN), tantalum silicon nitride (TaSiN) and tungsten nitride (WN).

8. The ferroelectric structure of claim 6, wherein the lower electrode further comprises a third lower electrode layer formed on the second lower electrode layer, the third lower electrode layer including a second metal oxide layer doped with a fourth metal.

9. The ferroelectric structure of claim 8, wherein the third lower electrode layer comprises the second metal oxide doped with the fourth metal by a concentration of about to 2 to about 5 atomic weight percent based on an entire atomic weight of the second metal oxide.

10. A ferroelectric capacitor comprising:
a ferroelectric layer on a lower electrode; and
an upper electrode on the ferroelectric layer, the upper electrode including a metal oxide and a metal.

11. The ferroelectric capacitor of claim 10, wherein the metal is different than a metal constituent in the metal oxide.

12. The ferroelectric capacitor of claim 10, wherein the metal comprises about 2 percent to about 5 percent of a total atomic weight of the metal oxide.

13. The ferroelectric capacitor of claim 10, wherein the metal oxide comprises strontium ruthenium oxide (SRO), strontium titanium oxide (STO), lanthanum nickel oxide (LNO) and/or calcium ruthenium oxide (CRO) and the metal comprises copper, lead and/or bismuth.

14. The ferroelectric capacitor of claim 10, wherein the metal comprises a first metal, the upper electrode further comprising:
a second metal that is different than the first metal.

15. The ferroelectric capacitor of claim 14, wherein the second metal comprises iridium (Ir), platinum (Pt), ruthenium (Ru), palladium (Pd) and/or gold (Au).

16. The ferroelectric capacitor of claim 14, wherein the metal oxide and the first metal comprise a first upper electrode layer, the upper electrode further comprising:
a second upper electrode on the first upper electrode comprising the second metal.

17. The ferroelectric capacitor of claim 16, wherein the lower electrode comprises a third metal that is different than or same as the second metal.

18. The ferroelectric capacitor of claim 17, wherein the third metal comprises iridium (1r), platinum (Pt), ruthenium (Ru), palladium (Pd) and/or gold (Au).

19. The ferroelectric capacitor of claim 17, wherein the third metal comprises a first lower electrode layer in the lower electrode and the metal oxide comprises a first metal oxide, the capacitor further comprising:
a second lower electrode layer on the first lower electrode layer, the second lower electrode layer comprising a second metal oxide and a fourth metal.

20. The ferroelectric capacitor of claim 19, wherein the second metal oxide comprises a different metal oxide or same metal oxide as the first metal oxide, and the fourth metal comprises a different metal or same metal as the first metal.

21. The ferroelectric capacitor of claim 20, wherein the fourth metal comprises about 2 percent to about 5 percent of a total atomic weight of the second metal oxide.

22. The ferroelectric capacitor of claim 19, wherein the second metal oxide comprises strontium ruthenium oxide (SRO), strontium titanium oxide (STO), lanthanum nickel oxide (LNO) and/or calcium ruthenium oxide (CRO) and the fourth metal comprises copper, lead and/or bismuth.

23. The ferroelectric capacitor of claim 19, further comprising:
a third lower electrode layer comprising a metal nitride beneath the first lower electrode layer.

24. The ferroelectric capacitor of claim 23, wherein the third lower electrode layer comprises titanium aluminum nitride (TiAlN), aluminum nitride (AlN), titanium nitride (TiN), titanium silicon nitride (TiSiN), tantalum nitride (TaN), tantalum silicon nitride (TaSiN) and/or tungsten nitride (WN).

25. The ferroelectric capacitor of claim 10, further comprising:
an insulation layer between the lower electrode and a substrate thereunder; and
an adhesion layer beneath on the insulation layer beneath the lower electrode.

26. The ferroelectric capacitor of claim 25, wherein the adhesion layer comprises titanium (Ti), tantalum (Ta), aluminum (Al), tungsten (W), titanium nitride (TiN), tantalum nitride (TaN), aluminum nitride (AlN) and/or tungsten nitride (WN).

27. A method of forming a ferroelectric capacitor comprising:
forming a ferroelectric layer on a lower electrode; and
forming an upper electrode on the ferroelectric layer, the upper electrode including a metal oxide and a metal.

28. The method of claim 27, wherein forming an upper electrode including a metal oxide and a metal comprises sputtering a metal oxide target doped with the metal, atomic layer deposition, or physical layer deposition.

29. The method of claim 27, wherein the metal comprises a first metal, the method further comprising:
forming a second metal on the first metal, the second metal being different than the first metal.

30. The method of claim 27, wherein the metal oxide and the first metal comprise a first upper electrode layer, method further comprising:
forming a second upper electrode on the first upper electrode comprising the second metal using ALD, PLD, or sputtering.

31. The method of claim 30, wherein forming the lower electrode comprises:
forming a third metal that is different than or same as the second metal using ALD, PLD, or sputtering.

32. The method of claim 31, wherein the third metal comprises a first lower electrode layer in the lower electrode and the metal oxide comprises a first metal oxide, the capacitor further comprising:
a second lower electrode layer on the first lower electrode layer, the second lower electrode layer comprising a second metal oxide and a fourth metal.

33. The method of claim 32, further comprising:
forming a third lower electrode layer comprising a metal nitride beneath the first lower electrode layer.

34. The method of claim 27, further comprising:
forming an insulation layer between the lower electrode and a substrate thereunder; and
forming an adhesion layer beneath on the insulation layer beneath the lower electrode.

35. A semiconductor device comprising:
a semiconductor substrate having a contact region;
an insulation layer formed on the semiconductor substrate;
a pad contacting the contact region through the insulation layer;
a lower electrode formed on the pad and the insulation layer, the lower electrode including a first metal;
a ferroelectric layer pattern formed on the lower electrode; and
an upper electrode formed on the ferroelectric layer pattern, the upper electrode including a first metal oxide doped with a second metal, and a third metal.

36. The semiconductor device of claim 35, wherein the upper electrode comprises:
a first upper electrode layer pattern formed on the ferroelectric layer pattern, the first upper electrode layer pattern including the first metal oxide doped with the second metal; and
a second upper electrode layer pattern formed on the first upper electrode layer pattern, the second upper electrode layer pattern including the third metal.

37. The semiconductor device of claim 36, wherein the lower electrode comprises:
a first lower electrode layer pattern formed on the pad and the insulation layer, the first lower electrode layer pattern including a metal nitride; and
a second lower electrode layer pattern formed on the first lower electrode layer pattern, the second lower electrode layer pattern including the first metal.

38. The semiconductor device of claim 37, wherein the lower electrode further comprises a third lower electrode layer pattern formed on the second lower electrode layer pattern, the third lower electrode layer pattern including a second metal oxide doped with a fourth metal.

39. A method of manufacturing a semiconductor device comprising:
forming a contact region on a semiconductor substrate;
forming an insulation layer on the semiconductor substrate;
forming a pad contacting the contact region through the insulation layer;
forming a lower electrode including a first metal on the pad and the insulation layer;
forming a ferroelectric layer pattern on the lower electrode; and
forming an upper electrode on the ferroelectric layer pattern, the upper electrode including a first metal oxide doped with a second metal, and a third metal.

40. The method of claim 39, wherein forming the upper electrode comprises:
forming a first upper electrode layer pattern including the third metal on the ferroelectric layer pattern; and
forming a second upper electrode layer pattern on the first upper electrode layer pattern, the second upper electrode layer pattern including the first metal oxide doped with the second metal.

41. The method of claim 40, wherein forming the lower electrode comprises:
forming a first lower electrode layer pattern including a metal nitride on the pad and the insulation layer; and
forming a second lower electrode layer pattern including the first metal on the first lower electrode layer pattern.

42. The method of claim 41, wherein forming the lower electrode further comprises forming a third lower electrode layer pattern on the second lower electrode layer pattern, the third lower electrode layer pattern being formed using a second metal oxide doped with a fourth metal.
